(19) United States
(12) Patent Application Publication
(10) Pub. No.: US 2021/0139643 A1
(43) Pub. Date: May 13, 2021

(54) POLYMER COMPOUND AND ORGANIC PHOTOELECTRIC CONVERSION ELEMENT USING SAME

(71) Applicant: SUMITOMO CHEMICAL COMPANY, LIMITED, Tokyo (JP)

(72) Inventors: Takafumi ARAKI, Ibaraki (JP); Kenichiro OHYA, Osaka (JP)

(73) Assignee: SUMITOMO CHEMICAL COMPANY, LIMITED, Tokyo (JP)

(21) Appl. No.: 16/071,307

(22) PCT Filed: Jan. 12, 2017
(86) PCT No.: PCT/JP2017/000751

§ 371 Date: Jul. 19, 2018

(30) Foreign Application Priority Data
Jan. 21, 2016 (JP) 2016-009484

(51) Int. Cl. C08G 61/12; C08K 9/04; C08K 3/04; H01L 51/00

(52) U.S. Cl. CPC C08G 61/126; C08K 9/04; C08K 3/04; H01L 51/0043; H01L 51/0036; H01L 51/4253; C08G 2261/1412; C08G 2261/3243; C08G 2261/149; C08G 2261/91; C08G 2261/12

(57) ABSTRACT

An object is to provide a polymer compound capable of producing an organic photoelectric conversion element having a large value of fill factor and the organic photoelectric conversion element. The present invention provides a polymer compound having a structural unit represented by the formula (I) and a structural unit represented by the formula (II).

[chemical structure]

Further provided is an organic photoelectric conversion element having a first electrode, a second electrode, and an active layer disposed between the first electrode and the second electrode, wherein the active layer comprises the polymer compound.

### TECHNICAL FIELD

The present invention relates to a polymer compound and an organic photoelectric conversion element using the same.

### BACKGROUND ART

Organic photoelectric conversion elements which comprise a polymer compound in an active layer has a potency to be produced inexpensively only by coating process, and have recently drawn attention. As the polymer compounds comprised in the active layer of the organic photoelectric conversion element, polymer compounds consisting of a structural unit represented by the formula (A) and a structural unit represented by the formula (B), and polymer compounds consisting of a structural unit represented by the formula (A) and a structural unit represented by the formula (C) have been reported (Patent Document 1).

[chemical structure]

### RELATED ART DOCUMENTS

Patent Document 1: JP 2014-031364 A

### DISCLOSURE OF INVENTION

### Problem to be Solved by the Invention

Organic photoelectric conversion elements with an active layer comprising the aforementioned polymer compound have been required to further improve the value of the fill factor.

The present invention aims to provide a polymer compound which enables the production of organic photoelectric conversion elements with a high value of fill factor, as well as the organic photoelectric conversion element.

### Means for Solving Problem

The present invention provides [1] to [14] below.

[1] A polymer compound having a structural unit represented by the formula (I) and a structural unit represented by the formula (II):

[chemical structure]

in the formula (I),

X¹ and X² each independently represent a sulfur atom or an oxygen atom,

Y¹ and Y² each independently represent C—(R⁵) or a nitrogen atom,

R¹, R², and R⁵ each independently represent a hydrogen atom, an alkyl group of 1 to 30 carbon atoms optionally having a substituent, a cycloalkyl group of 3 to 30 carbon atoms optionally having a substituent, an alkenyl group of 2 to 30 carbon atoms optionally having a substituent, a cycloalkenyl group of 3 to 30 carbon atoms optionally having a substituent, an alkynyl group of 2 to 30 carbon atoms optionally having a substituent, a cycloalkynyl group of 4 to 30 carbon atoms optionally having a substituent, an alkoxy group of 1 to 30 carbon atoms optionally having a substituent, a cycloalkoxy group of 3 to 30 carbon atoms optionally having a substituent, an alkylthio group of 1 to 30 carbon atoms optionally having a substituent, a cycloalkylthio group of 3 to 30 carbon atoms optionally having a substituent, a group represented by —C(═O)—R of 2 to 30 carbon atoms (R represents a hydrogen atom, an alkyl group, an aryl group, an alkoxy group, an aryloxy group, or a monovalent heterocyclic group), an aryl group of 6 to 30 carbon atoms optionally having a substituent, an aryloxy group of 6 to 30 carbon atoms optionally having a substituent, an arylthio group of 6 to 30 carbon atoms optionally having a substituent, a monovalent heterocyclic group of 2 to 30 carbon atoms optionally having a substituent, or a halogen atom;

[chemical structure]

in the formula (II),

X³ and X⁴ each independently represent a sulfur atom or an oxygen atom,

Y³ and Y⁴ each independently represent C—(R⁶) or a nitrogen atom,

R³, R⁴, and R⁶ each independently represent a hydrogen atom, an alkyl group of 1 to 30 carbon atoms optionally having a substituent, a cycloalkyl group of 3 to 30 carbon atoms optionally having a substituent, an alkenyl group of 2 to 30 carbon atoms optionally having a substituent, a cycloalkenyl group of 3 to 30 carbon atoms optionally having a substituent, an alkynyl group of 2 to 30 carbon atoms optionally having a substituent, a cycloalkynyl group of 4 to 30 carbon atoms optionally having a substituent, an alkoxy group of 1 to 30 carbon atoms optionally having a substituent, a cycloalkoxy group of 3 to 30 carbon atoms optionally having a substituent, an alkylthio group of 1 to 30 carbon atoms optionally having a substituent, a cycloalkylthio group of 3 to 30 carbon atoms optionally having a substituent, a group represented by —C(═O)—R of 2 to 30 carbon atoms (R represents a hydrogen atom, an alkyl group, an aryl group, an alkoxy group, an aryloxy group, or a monovalent heterocyclic group), an aryl group of 6 to 30 carbon atoms optionally having a substituent, an aryloxy group of 6 to 30 carbon atoms optionally having a substituent, an arylthio group of 6 to 30 carbon atoms optionally having a substituent, a monovalent heterocyclic group of 2 to 30 carbon atoms optionally having a substituent, or a halogen atom;

provided that there is no case where R¹ and R³ are the same and R² and R⁴ are the same at the same time.

[2] The polymer compound according to [1], wherein X¹, X², X³, and X⁴ are all a sulfur atom, and Y¹, Y², Y³, and Y⁴ are all C—H.
[3] The polymer compound according to [1] or [2], wherein R¹, R², R³, and R⁴ are an alkyl group of 1 to 30 carbon atoms optionally having a substituent, and R¹ and R² are the same and R³ and R⁴ are the same.
[4] The polymer compound according to any one of [1] to [3], wherein R¹, R², R³, and R⁴ are each independently an alkyl group of 12 to 19 carbon atoms optionally having a substituent.
[5] The polymer compound according to any one of [1] to [4], further having a structural unit represented by the formula

—Ar— (III)

in the formula (III),

a group represented by —Ar— represents an arylene group of 6 to 60 carbon atoms optionally having a substituent, or a divalent heterocyclic group optionally having a substituent,

provided that the structural unit represented by the formula (III) is different from the structural units represented by the formula (I) and the formula (II).

[6] The polymer compound according to [5], wherein the structural unit represented by the formula (III) is a structural unit represented by any of the formula (III-1) to formula (III-18),

[chemical structure]

[chemical structure]

[chemical structure]

in each of the formulae,

R^{a}, R^{b}, R^{c}, and R^{d} each independently represent a hydrogen atom, an alkyl group of 1 to 30 carbon atoms optionally having a substituent, a cycloalkyl group of 3 to 30 carbon atoms optionally having a substituent, an alkenyl group of 2 to 30 carbon atoms optionally having a substituent, a cycloalkenyl group of 3 to 30 carbon atoms optionally having a substituent, an alkynyl group of 2 to 30 carbon atoms optionally having a substituent, a cycloalkynyl group of 4 to 30 carbon atoms optionally having a substituent, an alkoxy group of 1 to 30 carbon atoms optionally having a substituent, a cycloalkoxy group of 3 to 30 carbon atoms optionally having a substituent, an alkylthio group of 1 to 30 carbon atoms optionally having a substituent, a cycloalkylthio group of 3 to 30 carbon atoms optionally having a substituent, a group represented by —C(═O)—R of 2 to 30 carbon atoms (R represents a hydrogen atom, an alkyl group, an aryl group, an alkoxy group, an aryloxy group, or a monovalent heterocyclic group), an aryl group of 6 to 30 carbon atoms optionally having a substituent, an aryloxy group of 6 to 30 carbon atoms optionally having a substituent, an arylthio group of 6 to 30 carbon atoms optionally having a substituent, a monovalent heterocyclic group of 2 to 30 carbon atoms optionally having a substituent, or a halogen atom, and

X^{a} and X^{b} each independently represent a sulfur atom or an O oxygen atom.

[7] The polymer compound according to [5] or [6], wherein the structural unit represented by the formula (III) is a structural unit represented by the formula (III-1) or the formula (III-15).
[8] The polymer compound according to any one of [1] to [7], further comprising a structural unit represented by the formula (IV):

[chemical structure]

in the formula (IV),

X⁵ and X⁶ each independently represent a sulfur atom or an oxygen atom,

Y⁵ and Y⁶ each independently represent C—(R⁹) or a nitrogen atom,

R⁷, R⁸, and R⁹ each independently represent a hydrogen atom, an alkyl group of 1 to 30 carbon atoms optionally having a substituent, a cycloalkyl group of 3 to 30 carbon atoms optionally having a substituent, an alkenyl group of 2 to 30 carbon atoms optionally having a substituent, a cycloalkenyl group of 3 to 30 carbon atoms optionally having a substituent, an alkynyl group of 2 to 30 carbon atoms optionally having a substituent, a cycloalkynyl group of 4 to 30 carbon atoms optionally having a substituent, an alkoxy group of 1 to 30 carbon atoms optionally having a substituent, a cycloalkoxy group of 3 to 30 carbon atoms optionally having a substituent, an alkylthio group of 1 to 30 carbon atoms optionally having a substituent, a cycloalkylthio group of 3 to 30 carbon atoms optionally having a substituent, a group represented by —C(═O)—R of 2 to 30 carbon atoms (R represents a hydrogen atom, an alkyl group, an aryl group, an alkoxy group, an aryloxy group, or a monovalent heterocyclic group), an aryl group of 6 to 30 carbon atoms optionally having a substituent, an aryloxy group of 6 to 30 carbon atoms optionally having a substituent, an arylthio group of 6 to 30 carbon atoms optionally having a substituent, a monovalent heterocyclic group of 2 to 30 carbon atoms optionally having a substituent, or a halogen atom;

provided that the structural unit represented by the formula (IV) represents a structural unit different from either the structural unit represented by the formula (I) or the structural unit represented by the formula (II) which the polymer compound has.

[9] A composition comprising the polymer compound according to any one of [1] to [8], and an electron-acceptor compound.
[10] The composition according to [9], wherein the electron-acceptor compound is a fullerene derivative.
[11] The composition according to [9] or [10], further comprising a solvent.
[12] An organic photoelectric conversion element comprising a first electrode, a second electrode, and an active layer disposed between the first electrode and the second electrode, wherein the active layer comprises the polymer compound according to any one of [1] to [8].
[13] An organic thin film solar cell comprising the organic photoelectric conversion element according to [12].
[14] An organic optical sensor comprising the organic photoelectric conversion element according to [12].

### DESCRIPTION OF EMBODIMENTS

The present invention will now be described in detail.

### Description of Common Terms

Hereinafter, the terms used in common herein have the following meanings unless otherwise specified.

A “polymer compound” means a polymer having a molecular weight distribution and a polystyrene-equivalent number-average molecular weight of 1,000 or more and 100,000,000 or less. The structural units included in the polymer compound are 100 mol % in total. The polymer compound may be any type of copolymer, including a block copolymer, a random copolymer, an alternating copolymer, and a graft copolymer.

A “structural unit” means a unit of a structure which the polymer compound has.

A “hydrogen atom” may be a light hydrogen atom or a deuterium atom.

A “halogen atom” means a fluorine atom, a chlorine atom, a bromine atom, or an iodine atom.

An “alkyl group” may be either straight or branched and may have a substituent. The number of carbon atoms of the straight alkyl group, which does not include the number of carbon atoms of the substituent, is usually 1 to 30, preferably 3 to 30, and more preferably 12 to 19. The number of carbon atoms of the branched alkyl group, which does not include the number of carbon atoms of the substituent, is usually 3 to 30, and more preferably 12 to 19.

Examples of the alkyl group optionally having a substituent may include non-substituted alkyl groups such as a methyl group, an ethyl group, an n-propyl group, an isopropyl group, an n-butyl group, an isobutyl group, a tert-butyl group, an n-pentyl group, an isoamyl group, a 2-ethylbutyl group, an n-hexyl group, an n-heptyl group, an n-octyl group, a 2-ethylhexyl group, a 3-n-propylheptyl group, an adamantyl group, an n-decyl group, a 3,7-dimethyloctyl group, a 3-heptyldodecyl group, a 2-ethyloctyl group, a 2-n-hexyl-decyl group, an n-dodecyl group, a tetradecyl group, a hexadecyl group, an octadecyl group, and an eicosyl group, and groups in which a hydrogen atom in these groups is substituted with an alkoxy group, an aryl group, a fluorine atom, or the like (substituted alkyl groups). Examples of the substituted alkyl group may include a trifluoromethyl group, a pentafluoroethyl group, a perfluorobutyl group, a perfluorohexyl group, a perfluorooctyl group, a 3-phenylpropyl group, a 3-(4-methylphenyl)propyl group, a 3-(3,5-di-n-hexylphenyl)propyl group, and a 6-ethyloxyhexyl group.

A “cycloalkyl group” may have a substituent. The number of carbon atoms of the cycloalkyl group, which does not include the number of carbon atoms of the substituent, is usually 3 to 30, and preferably 12 to 19.

Examples of the cycloalkyl group optionally having a substituent may include unsubstituted cycloalkyl groups such as a cyclohexyl group, and groups in which a hydrogen atom in these groups is substituted with an alkyl group, an alkoxy group, an aryl group, a fluorine atom, or the like (substituted cycloalkyl groups). Examples of the substituted cycloalkyl group may include a methylcyclohexyl group and an ethylcyclohexyl group.

An “alkenyl group” may be either straight or branched and may have a substituent. The number of carbon atoms of the straight alkenyl group, which does not include the number of carbon atoms of the substituent, is usually 2 to 30, and preferably 12 to 19. The number of carbon atoms of the branched alkenyl group, which does not include the number of carbon atoms of the substituent, is usually 3 to 30, and preferably 12 to 19.

Examples of the alkenyl group optionally having a substituent may include a vinyl group, a 1-propenyl group, a 2-propenyl group, a 2-butenyl group, a 3-butenyl group, a 3-pentenyl group, a 4-pentenyl group, a 1-hexenyl group, a 5-hexenyl group, and a 7-octenyl group.

A “cycloalkenyl group” may have a substituent. The number of carbon atoms of the cycloalkenyl group, which does not include the number of carbon atoms of the substituent, is usually 3 to 30, and preferably 12 to 19.

Examples of the cycloalkenyl group optionally having a substituent may include unsubstituted cycloalkenyl groups such as a cyclohexenyl group, and groups in which a hydrogen atom in these groups is substituted with an alkyl group, an alkoxy group, an aryl group, a fluorine atom, or the like (substituted cycloalkenyl groups). Examples of the substituted cycloalkenyl group may include a methylcyclohexenyl group and an ethylcyclohexenyl group.

An “alkynyl group” may be either straight or branched and may have a substituent. The number of carbon atoms of the alkynyl group, which does not include the number of carbon atoms of the substituent, is usually 2 to 30, and preferably 12 to 19. The number of carbon atoms of the branched alkynyl group, which does not include the number of carbon atoms of the substituent, is usually 4 to 30, and preferably 12 to 19.

Examples of the alkynyl group optionally having a substituent may include an ethynyl group, a 1-propynyl group, a 2-propynyl group, a 2-butynyl group, a 3-butynyl group, a 3-pentynyl group, a 4-pentynyl group, a 1-hexynyl group, and a 5-hexynyl group.

A “cycloalkynyl group” may have a substituent. The number of carbon atoms of the cycloalkynyl group, which does not include the number of carbon atoms of the substituent, is usually 4 to 30, and preferably 12 to 19.

Examples of the cycloalkynyl group optionally have a substituent may include unsubstituted cycloalkynyl groups such as a cyclohexynyl group and groups in which a hydrogen atom in these groups is substituted with an alkyl group, an alkoxy group, an aryl group, a fluorine atom, or the like (substituted cycloalkynyl groups). Examples of the substituted cycloalkynyl group may include a methylcyclohexynyl group and an ethylcyclohexynyl group.

An “alkoxy group” may be either straight or branched and may have a substituent. The number of carbon atoms of the straight alkoxy group, which does not include the number of carbon atoms of the substituent, is usually 1 to 30, and preferably 12 to 19. The number of carbon atoms of the branched alkoxy group, which does not include the number of carbon atoms of the substituent, is usually 3 to 30, and preferably 12 to 19.

Examples of the alkoxy group optionally having a substituent may include a methoxy group, an ethoxy group, an n-propyloxy group, an isopropyloxy group, an n-butyloxy group, an isobutyloxy group, a tert-butyloxy group, an n-pentyloxy group, an n-hexyloxy group, an n-heptyloxy group, an n-octyloxy group, a 2-ethylhexyloxy group, an n-nonyloxy group, an n-decyloxy group, a 3,7-dimethyloctyloxy group, a 3-heptyldodecyloxy group, and a lauryloxy group.

A “cycloalkoxy group” may have a substituent. The number of carbon atoms of the cycloalkoxy group, which does not include the number of carbon atoms of the substituent, is usually 3 to 30, and preferably 12 to 19.

Examples of the cycloalkoxy group optionally having a substituent may include a cyclohexyloxy group.

An “alkylthio group” may be either straight or branched and may have a substituent. The number of carbon atoms of the straight alkylthio group, which does not include the number of carbon atoms of the substituent, is usually 1 to 30, and preferably 12 to 19. The number of carbon atoms of the branched alkylthio group, which does not include the number of carbon atoms of the substituent, is usually 3 to 30, and preferably 12 to 19.

Examples of the alkylthio group optionally having a substituent may include a methylthio group, an ethylthio group, a propylthio group, an isopropylthio group, a butylthio group, an isobutylthio group, a tert-butylthio group, a pentylthio group, a hexylthio group, a heptylthio group, an octylthio group, a 2-ethylhexylthio group, a nonylthio group, a decylthio group, a 3,7-dimethyloctylthio group, a 3-heptyldodecylthio group, a laurylthio group, and a trifluoromethylthio group.

A “cycloalkylthio group” may have a substituent. The number of carbon atoms of the cycloalkylthio group, which does not include the number of carbon atoms of the substituent, is usually 3 to 30, and preferably 12 to 19.

Examples of the cycloalkylthio group optionally having a substituent may include a cyclohexylthio group.

The number of carbon atoms of the group represented by —C(═O)—R (R represents H (hydrogen atom), an alkyl group, an aryl group, an alkoxy group, an aryloxy group, or a monovalent heterocyclic group) is usually 2 to 30, and preferably 12 to 19.

Examples of the group represented by —C(═O)—R may include a methylcarbonyl group, an ethylcarbonyl group, a propylcarbonyl group, a butylcarbonyl group, a pentylcarbonyl group, a hexylcarbonyl group, a heptylcarbonyl group, an octylcarbonyl group, a nonylcarbonyl group, a decylcarbonyl group, an undecylcarbonyl group, a dodecylcarbonyl group, a tetradecylcarbonyl group, a 2-ethylhexylcarbonyl group, a 3,7-dimethyloctylcarbonyl group, 3-heptyldodecylcarbonyl group, a methoxycarbonyl group, an ethoxycarbonyl group, a propoxycarbonyl group, an isopropoxycarbonyl group, a butoxycarbonyl group, an isobutoxycarbonyl group, t-butoxycarbonyl group, a pentyloxycarbonyl group, a hexyloxycarboyl group, a cyclohexyloxycarbonyl group, a heptyloxycarbonyl group, an octyloxycarbonyl group, a nonyloxycarbonyl group, a decyloxycarbonyl group, a dodecyloxycarbonyl group, a tetradecyloxycarbonyl group, a 2-ethylhexyloxycarbonyl group, a 3,7-dimethyloctyloxycarbonyl group, a 3-heptyldodecyloxycarbonyl group, a trifluoromethoxycarbonyl group, a pentafluoroethoxycarbonyl group, a perfluorobutoxycarbonyl group, a perfluorohexyloxycarbonyl group, a perfluorooctyloxycarbonyl group, a phenylcarbonyl group, a pentafluorophenylcarbonyl group, a phenoxycarbonyl group, a naphthoxycarbonyl group, and a pyridyloxycarbonyl group.

An “aryl group” means an atomic group including remaining atoms obtained by removing, from an aromatic hydrocarbon, one hydrogen atom directly bonded to the carbon atom constituting the ring. The aryl group may have a substituent. The number of carbon atoms of the aryl group, which does not include the number of carbon atoms of the substituent, is usually 6 to 30, and preferably 6 to 10.

Examples of the aryl group optionally having a substituent may include a phenyl group, a 1-naphthyl group, a 2-naphthyl group, a 1-anthracenyl group, a 2-anthracenyl group, a 9-anthracenyl group, a 1-pyrenyl group, a 2-pyrenyl group, a 4-pyrenyl group, a 2-fluorenyl group, a 3-fluorenyl group, a 4-fluorenyl group, a 2-phenylphenyl group, a 3-phenylphenyl group, a 4-phenylphenyl group, and these groups having an alkyl group, an alkoxy group, an aryl group, a fluorine atom, or the like as a substituent.

An “aryloxy group” may have a substituent. The number of carbon atoms of the aryloxy group, which does not include the number of carbon atoms of the substituent, is usually 6 to 30, and preferably 6 to 10.

Examples of the aryloxy group optionally having a substituent may include a phenoxy group, a 1-naphthyloxy group, a 2-naphthyloxy group, a 1-anthracenyloxy group, a 9-anthracenyloxy group, a 1-pyrenyloxy group, and these groups having an alkyl group, an alkoxy group, a fluorine atom, or the like as a substituent.

An “arylthio group” may have a substituent. The number of carbon atoms of the arylthio group, which does not include the number of carbon atoms of the substituent, is usually 6 to 30, and preferably 6 to 10.

Examples of the arylthio group optionally having a substituent may include a phenylthio group, a C1-C12 alkyloxyphenylthio group (C1-C12 indicates that the number of carbon atoms is 1 to 12; the same shall apply hereinafter), a C1-C12 alkylphenylthio group, a 1-naphthylthio group, a 2-naphthylthio group, and a pentafluorophenylthio group.

A “p-valent heterocyclic group” (p represents an integer of 1 or greater) means an atomic group including remaining atoms obtained by removing, from a heterocyclic compound, p number of hydrogen atoms directly bonded to the carbon atom or heteroatom constituting the ring. Among the p-valent heterocyclic groups, the “p-valent aromatic heterocyclic group” which is an atomic group including remaining atoms obtained by removing, from an aromatic heterocyclic compound, p number of hydrogen atoms directly bonded to the carbon atom or heteroatom constituting the ring is preferable. The p-valent heterocyclic group may have a substituent.

The number of carbon atoms of the monovalent heterocyclic group, which does not include the number of carbon atoms of the substituent, is usually 2 to 30, and preferably 2 to 6.

Examples of the monovalent heterocyclic group optionally having a substituent may include a thienyl group, a pyrrolyl group, a furyl group, a pyridyl group, a piperidyl group, a quinolyl group, an isoquinolyl group, a pyrimidinyl group, a triazinyl group, and these groups having an alkyl group, an alkoxy group, or the like as a substituent.

<Polymer Compound>

The polymer compound of the present invention has at least two types of structural units, specifically, a structural unit represented by the formula (I) and a structural unit represented by the formula (II). The polymer compound of the present invention is preferably a conjugated polymer compound.

[chemical structure]

[in the formula (I),

X¹ and X² each independently represent S (sulfur atom) or O (oxygen atom),

Y¹ and Y² each independently represent C—(R⁵) or N (nitrogen atom),

R¹, R², and R⁵ each independently represent H (hydrogen atom), an alkyl group of 1 to 30 carbon atoms optionally having a substituent, a cycloalkyl group of 3 to 30 carbon atoms optionally having a substituent, an alkenyl group of 2 to 30 carbon atoms optionally having a substituent, a cycloalkenyl group of 3 to 30 carbon atoms optionally having a substituent, an alkynyl group of 2 to 30 carbon atoms optionally having a substituent, a cycloalkynyl group of 4 to 30 carbon atoms optionally having a substituent, an alkoxy group of 1 to 30 carbon atoms optionally having a substituent, a cycloalkoxy group of 3 to 30 carbon atoms optionally having a substituent, an alkylthio group of 1 to 30 carbon atoms optionally having a substituent, a cycloalkylthio group of 3 to 30 carbon atoms optionally having a substituent, a group represented by —C(═O)—R of 2 to 30 carbon atoms (R represents H (hydrogen atom), an alkyl group, an aryl group, an alkoxy group, an aryloxy group, or a monovalent heterocyclic group), an aryl group of 6 to 30 carbon atoms optionally having a substituent, an aryloxy group of 6 to 30 carbon atoms optionally having a substituent, an arylthio group of 6 to 30 carbon atoms optionally having a substituent, a monovalent heterocyclic group of 2 to 30 carbon atoms optionally having a substituent, or a halogen atom].

[chemical structure]

[in the formula (II),

X³ and X⁴ each independently represent S (sulfur atom) or O (oxygen atom),

Y³ and Y⁴ each independently represent C—(R⁶) or N (nitrogen atom),

R³, R⁴, and R⁶ each independently represent H (hydrogen atom), an alkyl group of 1 to 30 carbon atoms optionally having a substituent, a cycloalkyl group of 3 to 30 carbon atoms optionally having a substituent, an alkenyl group of 2 to 30 carbon atoms optionally having a substituent, a cycloalkenyl group of 3 to 30 carbon atoms optionally having a substituent, an alkynyl group of 2 to 30 carbon atoms optionally having a substituent, a cycloalkynyl group of 4 to 30 carbon atoms optionally having a substituent, an alkoxy group of 1 to 30 carbon atoms optionally having a substituent, a cycloalkoxy group of 3 to 30 carbon atoms optionally having a substituent, an alkylthio group of 1 to 30 carbon atoms optionally having a substituent, a cycloalkylthio group of 3 to 30 carbon atoms optionally having a substituent, a group represented by —C(═O)—R of 2 to 30 carbon atoms (R represents H (hydrogen atom), an alkyl group, an aryl group, an alkoxy group, an aryloxy group, or a monovalent heterocyclic group), an aryl group of 6 to 30 carbon atoms optionally having a substituent, an aryloxy group of 6 to 30 carbon atoms optionally having a substituent, an arylthio group of 6 to 30 carbon atoms optionally having a substituent, a monovalent heterocyclic group of 2 to 30 carbon atoms optionally having a substituent, or a halogen atom],

provided that there is no case where R¹ and R³ are the same and R² and R⁴ are the same at the same time. That is, there is no case where R¹ and R³ are the same and R² and R⁴ are the same at the same time, and there is no case where R¹ and R⁴ are the same and R² and R³ are the same at the same time.

Examples of the structural unit represented by the formula (I) may include structural units represented by the following formula (101) to formula (116). In the formula (101) to formula (116), R¹ and R² represent the same definitions as described above.

[chemical structure]

[chemical structure]

[chemical structure]

From the viewpoint of increasing the value of fill factor of the photoelectric conversion element produced using the polymer compound of the present invention, in the formula (I), X¹ and X² are preferably S (sulfur atom), and Y¹ and Y² are preferably C—H. The structural unit represented by the formula (I) preferably includes the structural units represented by the formula (101), the formula (102), the formula (105), and the formula (106) among the formula (101) to formula (116), more preferably the structural units represented by the formula (101) and the formula (102), and still more preferably the structural unit represented by the formula (101).

Examples of the structural unit represented by the formula (I) may include structural units represented by the following formula (201) to formula (212). In the formula (201) to formula (212), X¹, X², Y¹, and Y² represent the same definitions as described above.

[chemical structure]

[chemical structure]

[chemical structure]

[chemical structure]

From the viewpoint of increasing the value of fill factor of the photoelectric conversion element produced using the polymer compound of the present invention, in the formula (I), R¹ and R² are preferably an alkyl group. Examples of the structural unit represented by the formula (I) in which R¹ and R² are an alkyl group may include structural units represented by the following formula (301) to formula (315).

[chemical structure]

[chemical structure]

[chemical structure]

[chemical structure]

[chemical structure]

From the viewpoint of increasing the value of fill factor of the photoelectric conversion element produced using the polymer compound of the present invention, in the formula (I), R¹ and R² are preferably the same as each other. Among the structural units represented by the formula (301) to formula (315), the structural units represented by the formula (301) to formula (311) are preferable.

The number of carbon atoms of R¹ and R² is preferably 3 to 30, more preferably 4 to 20, and particularly preferably 12 to 19. Among the structural units represented by the formula (301) to formula (315), the formula (302) to formula (315) are preferable, the formula (302) to formula (314) are more preferable, and the formula (304) to formula (314) are still more preferable.

Examples of the structural unit represented by the formula (II) may include structural units represented by the following formula (401) to formula (416). In the formula (401) to formula (416), R³ and R⁴ represent the same definitions as described above.

[chemical structure]

[chemical structure]

[chemical structure]

From the viewpoint of increasing the value of fill factor of the photoelectric conversion element produced using the polymer compound of the present invention, in the formula (II), X³ and X⁴ are preferably S (sulfur atom), and Y³ and Y⁴ are preferably C—H. The structural unit represented by the formula (II) preferably includes the structural units represented by the formula (401), the formula (402), the formula (405), and the formula (406) among the formula (401) to formula (416), more preferably the structural units represented by the formula (401) and the formula (402), and still more preferably the structural unit represented by the formula (401).

Examples of the structural unit represented by the formula (II) may include structural units represented by the following formula (501) to formula (512). In the formula (501) to formula (512), X³, X⁴, Y³, and Y⁴ represent the same definitions as described above.

[chemical structure]

[chemical structure]

[chemical structure]

From the viewpoint of increasing the value of fill factor of the photoelectric conversion element produced using the polymer compound of the present invention, in the formula (II), R³ and R⁴ are preferably alkyl groups. Examples of the structural unit represented by the formula (II) in which R³ and R⁴ are alkyl groups may include structural units represented by the following formula (601) to formula (615).

[chemical structure]

[chemical structure]

[chemical structure]

[chemical structure]

[chemical structure]

From the viewpoint of increasing the value of fill factor of the photoelectric conversion element produced using the polymer compound of the present invention, in the formula (II), R³ and R⁴ are preferably the same as each other. Among the structural units represented by the formula (601) to formula (615), the structural units represented by the formula (601) to formula (611) are preferable.

The number of carbon atoms of R³ and R⁴ is preferably 3 to 30, more preferably 4 to 20, and particularly preferably 12 to 19. Among the structural units represented by the formula (601) to formula (615), the formula (602) to formula (615) are preferable, the formula (602) to formula (614) are more preferable, and the formula (604) to formula (614) are still more preferable.

The polymer compound of the present invention is preferably a polymer compound in which the structural unit represented by the formula (I) is the structural unit represented by the formula (201) and the structural unit represented by the formula (II) is the structural unit represented by the formula (605) or the structural unit represented by the formula (611), or a polymer compound in which the structural unit represented by the formula (I) is the structural unit represented by the formula (305) and the structural unit represented by the formula (II) is the structural unit represented by the formula (611), and more preferably a polymer compound in which the structural unit represented by the formula (I) is the structural unit represented by the formula (201) and the structural unit represented by the formula (II) is the structural unit represented by the formula (605).

The polymer compound having the structural unit represented by the formula (I) and the structural unit represented by the formula (II) preferably further has a structural unit represented by the formula (III) from the viewpoint of increasing the value of fill factor of the photoelectric conversion element produced using the polymer compound of the present invention. Preferably, the structural units represented by the formula (I) and the formula (II) and the structural unit represented by the formula (III) form conjugation. Conjugation in the present invention refers to a case where an unsaturated bond and a single bond are alternately present to show interaction. The unsaturated bond used herein refers to a double or triple bond.

[Chemical Formula 10]

—Ar— (III)

[in the formula (III),

a group represented by —Ar— represents an arylene group of 6 to 60 carbon atoms optionally having a substituent, or a divalent heterocyclic group optionally having a substituent,

provided that the structural unit represented by the formula (III) is different from the structural units represented by the formula (I) and the formula (II)]

The substituent which the arylene group represented by —Ar— may have may include an alkyl group, a cycloalkyl group, an alkenyl group, a cycloalkenyl group, an alkynyl group, a cycloalkynyl group, an alkoxy group, a cycloalkoxy group, an alkylthio group, a cycloalkylthio group, a group represented by —C(═O)—R (R represents H (hydrogen atom), an alkyl group, an aryl group, an alkoxy group, an aryloxy group, or a monovalent heterocyclic group), an aryl group, an aryloxy group, an arylthio group, a monovalent heterocyclic group, and a halogen atom.

The arylene group represented by —Ar— and optionally having a substituent may include a phenylene group; groups in which two or more phenylene groups are bonded such as a biphenyl-diyl group and a terphenyl-diyl group; and fused-ring compound groups such as a naphthalene-diyl group, an anthracene-diyl group, a fluorene-diyl group, a dihydrophenanthrene-diyl group, a phenanthrene-diyl group, and a pyrene-diyl group. Specific examples of these groups may include groups represented by the following formula (701) to formula (724). These groups may have a substituent.

[chemical structure]

[chemical structure]

[chemical structure]

[chemical structure]

Examples of the divalent hetrocyclic group optionally having a substituent represented by —Ar— may include groups obtained by removing two hydrogen atoms from heterocyclic compounds such as furan, thiophene, pyrrole, pyrroline, pyrrolidine, oxazole, isoxazole, thiazole, isothiazole, imidazole, imidazoline, imidazolidine, pyrazole, pyrazoline, prazolidine, furazan, triazole, thiadiazole, oxadiazole, tetrazole, pyran, pyridine, piperidine, thiopyran, pyridazine, pyrimidine, pyrazine, piperazine, morpholine, triazine, benzofuran, isobenzofuran, benzothiophene, indole, isoindole, indolizine, indoline, isoindoline, chromene, chroman, isochroman, benzopyran, quinoline, isoquinoline, quinolizine, benzimidazole, benzothiazole, indazole, naphthyridine, quinoxaline, quinazoline, quinazolidine, cinnoline, phthalazine, purine, pteridine, carbazole, xanthene, phenanthridine, acridine, β-carboline, perimidine, phenanthroline, thianthrene, phenoxathiin, phenoxazine, phenothiazine, and phenazine, these groups having a substituent, and divalent groups formed by bonding or fusing two or more of these groups. The substituent may include an alkyl group, a cycloalkyl group, an alkoxy group, a cycloalkoxy group, an alkylthio group, a cycloalkylthio group, an aryl group, a monovalent heterocyclic group, and a halogen atom.

The number of carbon atoms of the divalent heterocyclic group, which does not include the number of carbon atoms of the substituent, is usually 2 to 30, and preferably 2 to 18.

As the divalent heterocyclic group represented by —Ar—, a divalent aromatic heterocyclic group is preferable.

Specific examples of the divalent heterocyclic group may include groups represented by the formula (725) to formula (779).

[chemical structure]

[chemical structure]

[chemical structure]

[chemical structure]

[chemical structure]

From the viewpoint of increasing the value of fill factor, the structural unit represented by the formula (III) preferably is structural units represented by the formula (III-1) to the formula (III-18).

[chemical structure]

[chemical structure]

[chemical structure]

[in each of the formulae,

R^{a}, R^{b}, R^{c}, and R^{d} each independently represent H (hydrogen atom), an alkyl group of 1 to 30 carbon atoms optionally having a substituent, a cycloalkyl group of 3 to 30 carbon atoms optionally having a substituent, an alkenyl group of 2 to 30 carbon atoms optionally having a substituent, a cycloalkenyl group of 3 to 30 carbon atoms optionally having a substituent, an alkynyl group of 2 to 30 carbon atoms optionally having a substituent, a cycloalkynyl group of 4 to 30 carbon atoms optionally having a substituent, an alkoxy group of 1 to 30 carbon atoms optionally having a substituent, a cycloalkoxy group of 3 to 30 carbon atoms optionally having a substituent, an alkylthio group of 1 to 30 carbon atoms optionally having a substituent, a cycloalkylthio group of 3 to 30 carbon atoms optionally having a substituent, a group represented by —C(═O)—R of 2 to 30 carbon atoms (R represents H (hydrogen atom), an alkyl group, an aryl group, an alkoxy group, an aryloxy group, or a monovalent heterocyclic group), an aryl group of 6 to 30 carbon atoms optionally having a substituent, an aryloxy group of 6 to 30 carbon atoms optionally having a substituent, an arylthio group of 6 to 30 carbon atoms optionally having a substituent, a monovalent heterocyclic group of 2 to 30 carbon atoms optionally having a substituent, or a halogen atom, and

X^{a} and X^{b} each independently represent S (sulfur atom) or O (oxygen atom)]

As R^{a} to R^{d}, H (hydrogen atom), an alkyl group of 1 to 30 carbon atoms optionally having a substituent, an alkoxy group of 1 to 30 carbon atoms optionally having a substituent, and a halogen atom are preferable, and H (hydrogen atom), an alkyl group of 1 to 30 carbon atoms optionally having a substituent, and a fluorine atom are more preferable.

As the structural unit represented by the formula (III), the structural units represented by the formula (III-1), the formula (III-4), the formula (III-15), the formula (III-17), and the formula (III-18) are preferable, and the structural units represented by the formula (III-1) and the formula (III-15) are more preferable. Specific examples of the structural units represented by the formula (III-1), the formula (III-4), the formula (III-15), and the formula (III-18) may include structural units represented by the formula (III-1-1) to the formula (III-1-10), the formula (III-4-1) to formula (III-4-10), the formula (III-15-1) to formula (III-15-5), and the formula (III-18-1) to formula (III-18-6).

[chemical structure]

[chemical structure]

[chemical structure]

[chemical structure]

[chemical structure]

[chemical structure]

The polymer compound having the structural unit represented by the formula (I), the structural unit represented by the formula (II), and the structural unit represented by the formula (III) may include polymer compounds represented by the following formula (I-II-III-1) to formula (I-II-III-7). Although the following formula (I-II-III-1) to formula (I-II-III-7) do not specify the form of a block copolymer, a random copolymer, and an alternate copolymer, a random copolymer is preferable from the viewpoint of increasing the value of fill factor.

[chemical structure]

[chemical structure]

[in each formula,

X¹, X², X³, X⁴, Y¹, Y², Y³, Y⁴, R¹, R², R³, R⁴, X^{a}, X^{b}, R^{a}, and R^{b} represent the same definitions as described above, respectively,

X^{a}, X^{b}, R^{a}, and R^{b} which are plurally present in each formula may be the same as or different from one another,

X⁵ and X⁶ each independently represent S (sulfur atom) or O (oxygen atom),

Y⁵ and Y⁶ each independently represent C—(R⁵) or N (nitrogen atom),

R⁵ represents the same definition as described above, and

n1, n2, and n3 each represent mol % of a total number of each structural unit when the total number of all the structural units comprised in the polymer compound is 100 mol %, n1 in the polymer compounds represented by the formula (I-II-III-1) to the formula (I-II-III-5) is usually 1 to 99 and n2 is usually 1 to 99, and n1 in the polymer compounds represented by the formula (I-II-III-6) and the formula (I-II-III-7) is usually 1 to 98, n2 is usually 1 to 98, and n3 is usually 1 to 98]

When the polymer compound of the present invention includes the structural unit represented by the formula (III), from the viewpoint of increasing the value of fill factor, a copolymer in which the structural unit represented by the formula (I) or the structural unit represented by the formula (II), and the structural unit represented by the formula (III) are alternately bonded is preferable. That is, a copolymer in which the structural units represented by the formula (I) are not directly bonded to each other, the structural units represented by the formula (II) are not directly bonded to each other, the structural unit represented by the formula (I) and the structural unit represented by the formula (II) are not directly bonded to each other, and the structural units represented by the formula (III) are not directly bonded to each other, is preferable.

As the copolymer in which the structural units are alternately bonded, polymer compounds represented by the formula (I-II-III-1) to the formula (I-II-III-5) are preferable, and polymer compounds represented by the formula (I-II-III-1) or the formula (I-II-III-3) are more preferable.

Specific examples of the polymer compound having the structural unit represented by the formula (I), the structural unit represented by the formula (II), and the structural unit represented by the formula (III) may include polymer compounds represented by the formula (801) to formula (810) (n1, n2, and n3 represent the same definitions as those described above). Among these, the polymer compounds represented by the formula (801) to formula (807) and the formula (809) are preferable, the polymer compounds represented by the formula (801), the formula (803), the formula (805), the formula (807), and the formula (809) are more preferable, and the polymer compounds represented by the formula (801) and the formula (805) are still more preferable.

[chemical structure]

[chemical structure]

[chemical structure]

[chemical structure]

[chemical structure]

The polymer compound of the present invention may include a structural unit represented by the formula (IV) in addition to the structural unit represented by the formula (I) and the structural unit represented by the formula (II).

[chemical structure]

[in the formula (IV),

X⁵ and X⁶ each independently represent S (sulfur atom) or O (oxygen atom),

Y⁵ and Y⁶ each independently represent C—(R⁶) or N (nitrogen atom)

R⁷, R⁸, and R⁹ each independently represent H (hydrogen atom), an alkyl group of 1 to 30 carbon atoms optionally having a substituent, a cycloalkyl group of 3 to 30 carbon atoms optionally having a substituent, an alkenyl group of 2 to 30 carbon atoms optionally having a substituent, a cycloalkenyl group of 3 to 30 carbon atoms optionally having a substituent, an alkynyl group of 2 to 30 carbon atoms optionally having a substituent, a cycloalkynyl group of 4 to 30 carbon atoms optionally having a substituent, an alkoxy group of 1 to 30 carbon atoms optionally having a substituent, a cycloalkoxy group of 3 to 30 carbon atoms optionally having a substituent, an alkylthio group of 1 to 30 carbon atoms optionally having a substituent, a cycloalkylthio group of 3 to 30 carbon atoms optionally having a substituent, a group represented by —C(═O)—R of 2 to 30 carbon atoms (R represents H (hydrogen atom), an alkyl group, an aryl group, an alkoxy group, an aryloxy group, or a monovalent heterocyclic group), an aryl group of 6 to 30 carbon atoms optionally having a substituent, an aryloxy group of 6 to 30 carbon atoms optionally having a substituent, an arylthio group of 6 to 30 carbon atoms optionally having a substituent, a monovalent heterocyclic group of 2 to 30 carbon atoms optionally having a substituent, or a halogen atom], provided that the structural unit represented by the formula (IV) represents a structural unit different from the structural unit represented by the formula (I) and the structural unit represented by the formula (II).

Specific examples of the polymer compound having the structural unit represented by the formula (I), the structural unit represented by the formula (II), the structural unit represented by the formula (III), and the structural unit represented by the formula (IV) may include polymer compounds represented by the formula (811) and the formula (812) (n1, n2, and n3 represent the same definitions as those described above).

[chemical structure]

The polystyrene-equivalent weight-average molecular weight of the polymer compound of the present invention is preferably 3,000 to 10,000,000, more preferably 8,000 to 5,000,000, and still more preferably 10,000 to 100,000. When the weight-average molecular weight is less than 3,000, defects in film formation during the production of element may occur. When it is more than 10,000,000, its solubility to solvent or coating properties during the production of element may deteriorate.

The weight-average molecular weight in the present invention means a polystyrene-equivalent weight-average molecular weight calculated using gel permeation chromatography (GPC) and using a polystyrene standard sample.

When the polymer compound of the present invention is used in elements, it is desirable that the solubility of the polymer compound in the solvent is high from the viewpoint of the ease of production of the element. Specifically, the polymer compound of the present invention preferably has a solubility which allows the production of a solution comprising 0.01% by weight (wt %) or more of the polymer compound, more preferably a solubility which allows the production of a solution comprising 0.1 wt % or more of the polymer compound, and still more preferably a solubility which allows the production of a solution comprising 0.2 wt % or more of the polymer compound.

The polystyrene-equivalent number-average molecular weight of the polymer compound of the present invention is preferably 1×10³ to 1×10⁸. When the polystyrene-equivalent number-average molecular weight is 1×10³ or more, it is easy to obtain a tough thin film. When it is 1×10⁸ or less, the solubility is high, and the production of the thin film is facilitated.

The number-average molecular weight in the present invention means a polystyrene-equivalent number-average molecular weight calculated using gel permeation chromatography (GPC), using a polystyrene standard sample.

When the polymer compound has the structural unit represented by the formula (I) and the structural unit represented by the formula (II), the total number of the structural unit represented by the formula (I) and the total number of the structural unit represented by the formula (II) each are preferably 1 to 99 mol %, and more preferably 2.5 to 97.5 mol %, relative to the total number of all the structural units comprised in the polymer compound.

When the polymer compound has the structural unit represented by the formula (I), the structural unit represented by the formula (II), and the structural unit represented by the formula (III), the total number of the structural unit represented by the formula (I), the total number of the structural unit represented by the formula (II), and the total number of the structural unit represented by the formula (III) each are preferably 1 to 98 mol %, and more preferably 2.5 to 95.0 mol %, relative to the total number of all the structural units comprised in the polymer compound.

When the polymer compound has the structural unit represented by the formula (I), the structural unit represented by the formula (II), and the structural unit represented by the formula (IV), the total number of the structural unit represented by the formula (I), the total number of the structural unit represented by the formula (II), and the total number of the structural unit represented by the formula (IV) each are preferably 1 to 98 mol %, and more preferably 2.5 to 95.0 mol %, relative to the total number of all the structural units comprised in the polymer compound.

When the polymer compound has the structural unit represented by the formula (I), the structural unit represented by the formula (II), the structural unit represented by the formula (III), and the structural unit represented by the formula (IV), the total number of the structural unit represented by the formula (I), the total number of the structural unit represented by the formula (II), the total number of the structural unit represented by the formula (III), and the total number of the structural unit represented by the formula (IV) each are preferably 1 to 97 mol %, and more preferably 2.5 to 92.5 mol %, relative to the total number of all the structural units comprised in the polymer compound.

When the polymer compound has the structural unit represented by the formula (I), the structural unit represented by the formula (II), and the structural unit represented by the formula (III) (not comprising the structural unit represented by the formula (IV)), the total number of the structural unit represented by the formula (I), the structural unit represented by the formula (II), and the structural unit represented by the formula (III) is preferably 30 to 100 mol %, more preferably 50 to 100 mol %, and still more preferably 100 mol %, relative to the total number of all the structural units comprised in the polymer compound.

When the polymer compound has the structural unit represented by the formula (I), the structural unit represented by the formula (II), the structural unit represented by the formula (III), and the structural unit represented by the formula (IV), the total number of the structural unit represented by the formula (I), the structural unit represented by the formula (II), the structural unit represented by the formula (III), and the structural unit represented by the formula (IV) is preferably 30 to 100 mol %, more preferably 50 to 100 mol %, and still more preferably 100 mol %, relative to the total number of all the structural units comprised in the polymer compound.

In the polymer compound, a ratio of the total number (N_{I}) of the structural unit represented by the formula (I) to the sum of the total number (N_{I}) of the structural unit represented by the formula (I) and the total number (N_{II}) of the structural unit represented by the formula (II) (N_{I}/(N_{I}+N_{II})) is usually 0.01 to 0.99.

In the polymer compound, a ratio of the total number (N_{III}) of the structural unit represented by the formula (III) to the sum of the total number (N_{I}) of the structural unit represented by the formula (I) and the total number (N_{II}) of the structural unit represented by the formula (II) (N_{III}/(N_{I}+N_{II})) is usually 0 to 49. When the structural unit represented by the formula (III) is comprised, the above ratio (N_{III}/(N_{I}+N_{II})) is preferably 0.5 to 2.0.

In the polymer compound, a ratio of the total number (N_{IV}) of the structural unit represented by the formula (IV) to the sum of the total number (N_{I}) of the structural unit represented by the formula (I) and the total number (N_{II}) of the structural unit represented by the formula (II) (N_{IV}/(N_{I}+N_{II})) is usually 0 to 49. When the structural unit represented by the formula (IV) is comprised, the above ratio (N_{IV}/(N_{I}+N_{II})) is preferably 0.01 to 0.5.

Since the polymer compound of the present invention can exert high electron and/or hole transportability, when an organic thin film comprising the polymer compound is used for a element, the charge generated by the electron or hole injected from the electrode or by light absorption can be transported. Taking advantage of these properties, the polymer compound of the present invention can be suitably used in a variety of electronic elements such as organic photoelectric conversion elements, organic thin film transistors, organic electroluminescent elements, and the like.

<Method for Producing Polymer Compound>

The polymer compound of the present invention may be produced by any method. For example, the polymer compound can be synthesized by synthesizing a monomer having a functional group suitable for polymerization reaction to be used, dissolving the monomer in an organic solvent as necessary, and carrying out polymerization using a known aryl coupling reaction using a base, a catalyst, a ligand, and the like. The synthesis of the monomer may be performed with reference to the methods disclosed in JP 2006-182920 A, JP 2006-335933 A, and JP 2014-031364 A.

In the polymerization by the aryl coupling reaction, a solvent is usually used. The solvent may be selected in consideration of the polymerization reaction to be used, solubilities of the monomer and the polymer, and the like. Specifically, the solvent may include organic solvents such as tetrahydrofuran, toluene, 1,4-dioxane, dimethoxyethane, N,N-dimethylacetamide, and N,N-dimethylformamide, and mixed solvents obtained by mixing two or more of these solvents, and solvents having two phases of an organic solvent phase and an aqueous phase.

The lower limit of the reaction temperature of the aryl coupling reaction is preferably −100° C., more preferably −20° C., and still more preferably 0° C., from the viewpoint of reactivity. The upper limit of the reaction temperature is preferably 200° C., more preferably 150° C., and still more preferably 120° C., from the viewpoint of stability of the monomer and the compound.

In the polymerization by the aryl coupling reaction, the method of taking the polymer compound of the present invention from the reaction solution after completion of the reaction may include known methods. For example, the polymer compound of the present invention may be obtained by adding the reaction solution after completion of the reaction to a lower alcohol such as methanol, filtering the deposited precipitate, and drying the resulting filtrated product. When the purity of the obtained polymer compound is low, the polymer compound can be purified by recrystallization, continuous extraction with a Soxhlet extractor, column chromatography, and the like.

When the polymer compound of the present invention is used for the production of organic photoelectric conversion elements, it is preferable to protect the terminals of the polymer compound with a stable group because the presence of a polymerization active group at the terminals of the polymer compound may result in deterioration of the durability and other properties of the organic photoelectric conversion elements.

The stable, terminal protecting group may include an alkyl group, an alkoxy group, a fluoroalkyl group, a fluoroalkoxy group, an aryl group, an arylamino group, a monovalent heterocyclic group, and the like. The arylamino group may include a phenylamino group, a diphenylamino group, and the like. The monovalent heterocyclic group may include a thienyl group, a pyrrolyl group, a furyl group, a pyridyl group, a quinolyl group, an isoquinolyl group, and the like. A polymerization active group remaining at the terminal of the polymer compound may be substituted with a hydrogen atom instead of the stable group. From the viewpoint of enhancing hole transportability, it is preferable that a stable group which protects the terminals is an electron donating group such as an arylamino group. When the polymer compound is a conjugated polymer compound, groups having conjugated bonds which may continue the conjugated structure of the polymer compound in its main chain and the conjugated structure of a stable group which protects the terminals can also be used as the stable group which protects the terminals. Examples of such a group may include an aryl group, and a monovalent heterocyclic group having aromaticity.

Examples of the polymerization by the aryl coupling reaction may include polymerization by the Suzuki coupling reaction, polymerization by the Stille coupling reaction, polymerization by the Yamamoto coupling reaction, and polymerization by the Kumada-Tamao coupling reaction.

Among the polymerizations by the aryl coupling reaction, from the viewpoint of reactivity, a method of polymerization by the Stille coupling reaction, a method of polymerization by the Suzuki coupling reaction, and a method of polymerization by the Yamamoto coupling reaction are preferable. Preferably, the method of polymerization by the Yamamoto coupling reaction is a method of polymerization by the Yamamoto coupling reaction using a nickel-zerovalent complex.

(Polymerization by Suzuki Coupling Reaction)

Examples of the method using the Suzuki coupling reaction may include a production method including a step of reacting one or more types of compounds represented by the formula (901):

Q¹-E¹-Q² (901)

[in the formula,

E¹ represents the structural unit represented by the formula (III), and

Q¹ and Q² are the same as or different from each other, and represent a boric acid residue (—B(OH)₂), a boric acid ester residue, or a borate salt residue] with two or more types of compounds represented by the formula (902):

T¹-E²-T² (902)

[in the formula,

E² represents the structural unit represented by the formula (I), the formula (II), or the formula (III), and

T¹ and T² each independently represent a halogen atom]

in the presence of a palladium catalyst and a base. The foregoing production method can provide the polymer compound including the structural unit represented by the formula (I), the structural unit represented by the formula (II), and the structural unit represented by the formula (III). However, the two or more types of compounds represented by the formula (902) include a compound of the formula (902) in which E² is the structural unit represented by the formula (I) and a compound of the formula (902) in which E² is the structural unit represented by the formula (II). Preferably, E¹ is any of structural units represented by the (III-1) to formula (III-18).

When the compound represented by the formula (901) is reacted with the compound represented by the formula (902), it is preferable that the sum of the moles of the two or more types of compounds represented by the formula (902) used in the reaction is in excess of the sum of the moles of the one or more types of compounds represented by the formula (901) used in the reaction. If the sum of the moles of the two or more types of compounds represented by the formula (902) used in the reaction is 1 mole, the sum of the moles of the one or more types of compounds represented by the formula (901) is preferably 0.6 to 0.99 moles, and more preferably 0.7 to 0.95 moles.

The boric acid ester residue represents a group obtained by removing a hydroxyl group from a boric acid diester. Specific examples of the boric acid ester residue and the borate salt residue may include groups represented by the following formulae.

[chemical structure]

[In the formula, Me represents a methyl group, Et represents an ethyl group, and M⁺ represents a metal ion]

The metal ion may include alkali metal ions such as lithium, sodium, potassium, and cesium.

The halogen atom represented by T¹ and T² in the formula (902) is preferably a bromine atom or an iodine atom, and more preferably a bromine atom, from the viewpoint of easy synthesis of the polymer compound.

Specifically, the Suzuki coupling reaction may include a method of carrying out the reaction in any solvent using a palladium catalyst as a catalyst and in the presence of a base.

Examples of the palladium catalyst used in the Suzuki coupling reaction may include Pd(0) catalysts, and Pd(II) catalysts. Specific examples thereof may include palladium [tetrakis(triphenylphosphine)], palladium acetates, dichlorobis(triphenylphosphine) palladium, palladium acetate, tris(dibenzylideneacetone) dipalladium, and bis(dibenzylideneacetone) palladium. From the viewpoint of ease of reaction (polymerization) operation and reaction (polymerization) rate, dichlorobis (triphenylphosphine) palladium, palladium acetate, and tris(dibenzylideneacetone) dipalladium are preferable. The amount of the palladium catalyst to be added is not particularly limited, and may be an effective amount as a catalyst, but is usually 0.0001 mol to 0.5 mol, and preferably 0.0003 mol to 0.1 mol, relative to 1 mol of the compound represented by the formula (901).

When the palladium acetates are used as the palladium catalyst for use in the Suzuki coupling reaction, phosphorous compounds such as triphenylphosphine, tri(o-tolyl)phosphine, or tri(o-methoxyphenyl)phosphine can be added as a ligand. In this case, the amount of the ligand added is usually 0.5 mol to 100 mol, preferably 0.9 mol to 20 mol, and more preferably 1 mol to 10 mol, relative to 1 mol of the palladium catalyst.

The base used in the Suzuki coupling reaction may include inorganic bases, organic bases, inorganic salts, and the like. Examples of the inorganic base may include potassium carbonate, sodium carbonate, barium hydroxide, and potassium phosphate. Examples of the organic base may include triethylamine and tributylamine. Examples of the inorganic salt may include cesium fluoride. The amount of the base added is usually 0.5 mol to 100 mol, preferably 0.9 mol to 20 mol, and more preferably 1 mol to 10 mol, relative to 1 mol of the compound represented by the formula (901).

The Suzuki coupling reaction is usually carried out in a solvent. Examples of the solvent may include organic solvents such as N,N-dimethylformamide, toluene, dimethoxyethane, tetrahydrofuran, methylene chloride, 1,4-dioxane, N,N-dimethylacetamide, N,N-dimethylformamide, and mixed solvents obtained by mixing two or more of these solvents, and solvents having two phases of an organic solvent phase and an aqueous phase. From the viewpoint of the solubility of the polymer compound used in the present invention, toluene or tetrahydrofuran is preferable. The solvent used in the Suzuki coupling reaction is preferably deoxygenated prior to the reaction to suppress the side reaction. The solvent having two phases of an organic solvent phase and an aqueous phase may include those having two phases of an aqueous phase and an organic solvent phase obtained by adding an aqueous solution comprising the aforementioned base to the aforementioned organic solvent. When an inorganic salt is used as the base, from the viewpoint of solubility of the inorganic salt, an aqueous solution comprising a base is usually added to the reaction liquid for reaction. If the reaction is carried out in a two-phase system, a phase transfer catalyst such as a quaternary ammonium salt may be added as necessary.

The temperatures at which the Suzuki coupling reaction is carried out are usually in a range of about 40 to about 160° C., depending on the solvent. From the viewpoint of the high molecular weight of the polymer compound, a range of 60 to 120° C. is preferable. The reaction system may be heated to near the boiling point of the solvent and refluxed.

The end point of the reaction time may be the time when the desired degree of polymerization is achieved, but it is usually about 0.1 hour to about 200 hours. About 0.5 hour to about 30 hours are efficient and preferable.

The Suzuki coupling reaction is carried out in a reaction system in which the palladium-catalyst is not deactivated, and in an inert atmosphere. For example, the reaction is carried out in the system the inside atmosphere of which is sufficiently replaced with argon gas, nitrogen gas, etc. Specifically, the inside atmosphere of the polymerization vessel (reaction system) is sufficiently replaced with nitrogen gas, a compound represented by the formula (901), a compound represented by the formula (902), and a palladium catalyst, for example, dichlorobis(triphenylphosphine)palladium (II) are charged into the polymerization vessel. The inside atmosphere of the polymerization vessel is sufficiently replaced with nitrogen gas again, and a solvent, for example, toluene bubbled with nitrogen gas in advance is added. A basic aqueous solution, for example, an aqueous sodium carbonate solution bubbled with nitrogen gas is dropwisely added to the obtained solution, and the mixture is then heated to raise the temperature in order to carry out the polymerization for 8 hours at reflux temperature, while maintaining an inert atmosphere.

(Polymerization by Stille Coupling Reaction)

Examples of the method using the Stille coupling reaction may include a production method including a step of reacting one or more types of compounds represented by the formula (903):

Q³-E³-Q⁴ (903)

[in the formula,

E³ represents the structural unit represented by the formula (III), and

Q³ and Q⁴ each independently represent a group represented by —SnR^{e}₃ (R^{e} represents an alkyl group of 1 to 50 carbon atoms, a cycloalkyl group of 3 to 50 carbon atoms, or an aryl group of 6 to 60 carbon atoms)]

with two or more types of compounds represented by the aforementioned formula (902), in the presence of a palladium catalyst. E³ is preferably any of structural units represented by the formula (III-1) to the formula (III-18).

The alkyl group of 1 to 50 carbon atoms represented by R^{e} may include a methyl group, an ethyl group, a propyl group, an isopropyl group, a butyl group, an isobutyl group, a sec-butyl group, a tert-butyl group, a pentyl group, an isopentyl group, a 2-methylbutyl group, a 1-methylbutyl group, a hexyl group, an isohexyl group, a 3-methylpentyl group, a 2-methylpentyl group, a 1-methylpentyl group, a heptyl group, an octyl group, an isooctyl group, a 2-ethylhexyl group, a nonyl group, a decyl group, an undecyl group, a dodecyl group, a tetradecyl group, a hexadecyl group, an octadecyl group, an eicosyl group, and the like.

The cycloalkyl group of 3 to 50 carbon atoms represented by R^{e} may include a cyclopentyl group, a cyclohexyl group, an adamantly group, and the like.

The aryl group of 6 to 60 carbon atoms represented by R^{e} may include a phenyl group a naphthyl group, and the like.

The group represented by —SnR^{e}₃ are preferably —SnMe₃, —SnEt₃, —SnBu₃, and —SnPh₃, and more preferably —SnMe₃, —SnEt₃, and —SnBu₃ (Me represents a methyl group, Et an ethyl group, Bu a butyl group, and Ph a phenyl group).

The halogen atom represented by T¹ and T² in the formula (902) is preferably a bromine atom or an iodine atom from the viewpoint of easy synthesis of the polymer compound.

Specifically, the Stille coupling reaction may include a method of carrying out the reaction in any solvent in the presence of a palladium catalyst as a catalyst.

Examples of the palladium catalyst used in the Stille coupling reaction may include Pd(0) catalysts, and Pd(II) catalysts. Specifically, the palladium catalyst may include palladium [tetrakis(triphenylphosphine)], palladium acetates, dichlorobis(triphenylphosphine) palladium, palladium acetate, tris(dibenzylideneacetone) dipalladium, and bis(dibenzylideneacetone) palladium. From the viewpoint of ease of reaction (polymerization) operation and reaction (polymerization) rate, palladium [tetrakis(triphenylphosphine)] and tris(dibenzylideneacetone) dipalladium are preferable. The amount of the palladium catalyst to be used in the Stille coupling reaction is not particularly limited, and may be an effective amount as a catalyst, but is usually 0.0001 mol to 0.5 mol, and preferably 0.0003 mol to 0.2 mol, relative to 1 mol of the compound represented by the formula (902).

A ligand and a co-catalyst may also be used, as necessary, in the Stille coupling reaction. Examples of the ligand may include phosphorus compounds such as triphenylphosphine, tri(o-tolyl)phosphine, tri(o-methoxyphenyl)phosphine and tris(2-furyl)phosphine, and arsenic compounds such as triphenylarsine and triphenoxyarsine. The co-catalyst may include copper iodide, copper bromide, copper chloride, copper(I) 2-thenoylate, and the like. When a ligand or co-catalyst is used, the amount of the ligand or co-catalyst added is usually 0.5 mol to 100 mol, preferably 0.9 mol to 20 mol, and more preferably 1 mol to 10 mol, relative to 1 mol of palladium catalyst.

The Stille coupling reaction is usually carried out in a solvent. The solvent may include organic solvents such as N,N-dimethylformamide, N,N-dimethylacetamide, toluene, dimethoxyethane, tetrahydrofuran, and mixed solvents obtained by mixing two or more of these solvents, solvents having two phases of an organic solvent phase and an aqueous phase, and the like. From the viewpoint of solubility of the polymer compound used in the present invention, toluene and tetrahydrofuran are preferable. The solvent used in the Stille coupling reaction is preferably deoxygenated prior to the reaction to suppress the side reaction.

The temperatures at which the Stille coupling reaction is carried out are usually in a range of about 50 to about 160° C., depending on the solvent. From the viewpoint of the high molecular weight of the polymer compound, a range of 60 to 120° C. is preferable. The reaction system may be heated to near the boiling point of the solvent and refluxed.

The end point of the time during which the reaction is carried out (reaction time) may be the time when the desired degree of polymerization is achieved, but is usually about 0.1 hour to about 200 hours. About 1 hour to about 30 hours are efficient and preferable.

The Stille coupling reaction is carried out in a reaction system in which the Pd (palladium) catalyst is not deactivated, and in an inert atmosphere. For example, the reaction is carried out in the system the inside atmosphere of which is sufficiently replaced with argon gas, nitrogen gas, etc. Specifically, the inside atmosphere of the polymerization vessel (reaction system) is sufficiently replaced with nitrogen gas, and degassed, and then a compound represented by the formula (903), a compound represented by the formula (902), and a palladium catalyst are charged into the polymerization vessel. The inside atmosphere of the polymerization vessel is again sufficiently replaced with nitrogen gas, and a solvent, for example, toluene bubbled with nitrogen gas in advance is added thereto. Then, a ligand and a co-catalyst are added, if necessary. After that, the mixture is heated to raise the temperature in order to carry out the polymerization for 8 hours at reflux temperature, while maintaining an inert atmosphere.

(Polymerization by Yamamoto Coupling Reaction)

Polymerization by Yamamoto coupling reaction is polymerization using a catalyst and a reducing agent to react monomers having a halogen atom with each other, monomers having a sulfonate group such as a trifluoromethanesulfonate group with each other, or a monomer having a halogen atom with a monomer having a sulfonate group.

The catalyst may include catalysts comprising a nickel zerovalent complex such as bis(cyclooctadiene)nickel and a ligand such as bipyridyl, and catalysts comprising a nickel complex other than a nickel zerovalent complex, such as [bis(diphenylphosphino)ethane]nickel dichloride and [bis(diphenylphosphino)propane]nickel dichloride, and, as necessary, a ligand such as triphenylphosphine, diphenylphosphino propane, tri(cyclohexyl)phosphine and tri(tert-butyl) phosphine.

As a solvent used in the Yamamoto coupling reaction, organic solvents such as tetrahydrofuran, toluene, 1,4-dioxane, dimethoxyethane, N,N-dimethylacetamide, N,N-dimethylformamide, and mixtures of two or more of these solvents are preferable. Preferably, the solvent used in the Yamamoto coupling reaction is deoxygenated prior to the reaction to suppress the side reaction.

Examples of the reducing agent may include zinc and magnesium.

The polymerization by the Yamamoto coupling reaction may use a dehydrated solvent in the reaction, may be carried out in an inert atmosphere, and may be carried out by adding a dehydrating agent into the reaction system.

The details of the polymerization by the Yamamoto coupling reaction are described in, for example, Macromolecules, 1992, No. 25, pp. 1214-1223.

(Polymerization by Kumada-Tamao Coupling Reaction)

Polymerization by Kumada-Tamao coupling reaction is polymerization using a nickel catalyst such as [bis(diphenylphosphino)ethane]nickel dichloride and [bis(diphenylphosphino)propane]nickel dichloride to react a compound having a magnesium halide group with a compound having a halogen atom. The magnesium halide group is a group represented by —MgX (X represents a halogen atom).

The polymerization by the Kumada-Tamao coupling reaction may use a dehydrated solvent in the reaction, may be carried out in an inert atmosphere, and may be carried out by adding a dehydrating agent into the reaction system.

<Organic Photoelectric Conversion Element>

The organic photoelectric conversion element of the present invention has a first electrode, a second electrode, and an active layer which comprises the polymer compound of the present invention and is disposed between the first and second electrodes.

The organic photoelectric conversion element of the present invention is an organic photoelectric conversion element having a first electrode, a second electrode, and an active layer disposed between the first and second electrodes. It is preferable that one of the first and second electrodes is transparent or translucent, the active layer has an electron-donating compound and an electron-acceptor compound, and the organic photoelectric conversion element comprises the polymer compound of the present invention as an electron-donating compound.

The organic photoelectric conversion element may include components other than the electrodes and the active layer, and may include, for example, a substrate, a hole transport layer, an electron transport layer, and the like. Examples of the organic photoelectric conversion element of the present invention may include organic photoelectric conversion elements including a substrate, a first electrode, a hole transport layer, an active layer, and a second electrode disposed in this order, and organic photoelectric conversion elements including a first electrode, a hole transport layer, an active layer, an electron transport layer, and a second electrode disposed in this order.

(Substrate)

The organic photoelectric conversion element produced using the polymer compound of the present invention is generally formed on a substrate. The substrate may be any substrate as long as it does not chemically change when an electrode is formed and an organic layer is then formed. Examples of the material of the substrate may include glass, plastic, a polymer film, and silicon. In the case of an opaque substrate, the opposite electrode (i.e., the electrode far from the substrate) is preferably transparent or translucent.

(First Electrode and Second Electrode)

The transparent or translucent electrode material may include a conductive metal oxide film, a translucent metal thin film, and the like. Specifically, conductive materials such as indium oxide, zinc oxide, tin oxide, and their composite materials such as indium tin oxide (ITO), indium zinc oxide, and the like, NESA, gold, platinum, silver, and copper are used, and ITO, indium zinc oxide, and tin oxide are preferable. The production method of the electrode may include a vacuum deposition method, a sputtering method, an ion plating method, a plating method, and the like.

As the electrode material, organic transparent conductive films such as polyaniline and derivatives thereof, polythiophene and derivatives thereof may be used.

One of the electrodes may not be transparent, and as the electrode material of the electrode, metals, conductive polymers, etc. may be used. Specific examples of the electrode material may include metals such as lithium, sodium, potassium, rubidium, cesium, magnesium, calcium, strontium, barium, aluminum, scandium, vanadium, zinc, yttrium, indium, cerium, samarium, europium, terbium, ytterbium, and the like, and alloys of two or more thereof, alloys of one or more of the metals as above and one or more metals selected from the group consisting of gold, silver, platinum, copper, manganese, titanium, cobalt, nickel, tungsten, and tin, graphite, graphite interlayer compounds, polyaniline and derivatives thereof, and polythiophene and derivatives thereof. The alloy may include a magnesium-silver alloy, a magnesium-indium alloy, a magnesium-aluminum alloy, an indium-silver alloy, a lithium-aluminum alloy, a lithium-magnesium alloy, a lithium-indium alloy, a calcium-aluminum alloy, and the like.

(Hole Transport Layer)

The hole transport layer has an electron blocking function. By providing the hole transport layer, photoelectric conversion elements with higher photoelectric conversion efficiency can be obtained. The hole transport layer comprises, for example, PEDOT (poly-3,4-ethylenedioxythiophene) and the like.

(Active Layer)

The active layer may comprise one type of the polymer compound of the present invention solely or two or more types thereof in combination. In order to enhance the hole transportability of the active layer, a compound other than the polymer compound of the present invention may also be used and mixed in the active layer as an electron-donating compound and/or an electron-acceptor compound. The electron-donating compound/the electron-acceptor compound is relatively determined from the energy level of the energy levels of these compounds.

Examples of the electron-donating compound may include, in addition to the polymer compound of the present invention, pyrazoline derivatives, arylamine derivatives, stilbene derivatives, triphenyldiamine derivatives, oligothiophenes and derivatives thereof, polyvinylcarbazoles and derivatives thereof, polysilanes and derivatives thereof, polysiloxane derivatives having an aromatic amine residue in the side chain or main chain, polyanilines and derivatives thereof, polythiophenes and derivatives thereof, polypyrroles and derivatives thereof, polyphenylenevinylenes and derivatives thereof, and polythienylenevinylenes and derivatives thereof.

Examples of the electron-acceptor compound may include, in addition to the polymer compound of the present invention, carbon materials, metal oxides such as titanium oxide, oxadiazole derivatives, anthraquinodimethane and derivatives thereof, benzoquinone and derivatives thereof, naphthoquinone and derivatives thereof, anthraquinone and derivatives thereof, tetracyanoanthraquinodimethane and derivatives thereof, fluorenone derivatives, diphenyldicyanoethylene and derivatives thereof, diphenoquinone derivatives, metal complexes of 8-hydroxyquinoline and derivatives thereof, polyquinoline and derivatives thereof, polyquinoxaline and derivatives thereof, polyfluorene and derivatives thereof, phenanthroline derivatives such as 2,9-dimethyl-4,7-diphenyl-1,10-phenanthroline (bathocuproine), fullerene, and fullerene derivatives. Titanium oxide, carbon nanotube, fullerene, and fullerene derivatives are preferable, and fullerene and fullerene derivatives are more preferable.

Examples of fullerene and fullerene derivatives may include C₆₀, C₇₀, C₇₆, C₇₈, C₈₄, and derivatives thereof. The fullerene derivative represents a compound obtained by modifying at least a part of fullerene.

Examples of the fullerene derivative may include compounds represented by the formula (1001) to formula (1004).

[chemical structure]

[In the formulae (1001) to (1004), R^{x}, R^{y}, and R^{z} are an alkyl group of 1 to 50 carbon atoms optionally having a substituent, a cycloalkyl group of 3 to 50 carbon atoms optionally having a substituent, an aryl group of 6 to 60 carbon atoms optionally having a substituent, a monovalent heterocyclic group of 2 to 30 carbon atoms optionally having a substituent, or a group having an ester structure of 2 to 30 carbon atoms]

Examples of the monovalent heterocyclic group represented by R^{x}, R^{y}, and R^{z} may include a thienyl group, a pyrrolyl group, a furyl group, a pyridyl group, a quinolyl group, and an isoquinolyl group.

Examples of the group having an ester structure represented by R^{x}, R^{y}, and R^{z} may include a group represented by the formula (1005).

[chemical structure]

[In the formula,

m is an integer of 1 to 6.

n is an integer of 0 to 6.

R^{v} represents an alkyl group of 1 to 50 carbon atoms optionally having a substituent, a cycloalkyl group of 3 to 50 carbon atoms optionally having a substituent, an aryl group of 6 to 60 carbon atoms optionally having a substituent, and a monovalent heterocyclic group of 2 to 30 carbon atoms optionally having a substituent]

Specific examples of the C60 fullerene derivative may include compounds represented by the formula (1006) to formula (1012)

[chemical structure]

Specific examples of the C70 fullerene derivative may include compounds represented by the formula (1013) to formula (1015).

[chemical structure]

Examples of the fullerene derivative may include [6,6]-phenyl C61 butyric acid methyl ester (C60PCBM, [6,6]-Phenyl C61 butyric acid methyl ester), [6,6]-phenyl C71 butyric acid methyl ester (C70PCBM, [6,6]-Phenyl C71 butyric acid methyl ester), [6,6]-phenyl C85 butyric acid methyl ester (C84PCBM, [6,6]-Phenyl C85 butyric acid methyl ester), and [6,6]-thienyl C61 butyric acid methyl ester ([6,6]-Thienyl C61 butyric acid methyl ester).

When the active layer comprises the polymer compound of the present invention and the fullerene derivative, the amount of the fullerene derivative is preferably 10 to 1000 parts by weight, and more preferably 20 to 500 parts by weight, relative to 100 parts by weight of the polymer compound of the present invention.

The thickness of the active layer is usually 1 nm to 100 μm, preferably 2 nm to 1,000 nm, more preferably 5 nm to 500 nm, and still more preferably 20 nm to 200 nm.

(Electron Transport Layer)

The electron transport layer has a hole blocking function. By providing an electron transport layer, photoelectric conversion elements with higher photoelectric conversion efficiency can be obtained. The electron transport layer includes, for example, a halide of an alkali metal and an alkaline earth metal such as lithium fluoride, a metal oxide such as titanium oxide or zinc oxide, or a polyethyleneimine ethoxylate.

<Composition Comprising Polymer Compound>

As the composition comprising the polymer compound of the present invention, a composition comprising the polymer compound of the present invention and an electron-acceptor compound may be mentioned. The composition may further comprise a solvent. Examples of the solvent may include chlorobenzene, dichlorobenzene, chloronaphthalene, toluene, xylene, mesitylene, pseudocumene, tetramethylbenzene, tetrahydronaphthalene, indane, methylnaphthalene, diiodooctane, methyl benzoate, acetophenone, and propiophenone. It is preferable that the total weight of the solvent comprised in the composition is 70% by weight or more relative to the total weight of the composition.

<Production Method of Organic Photoelectric Conversion Element>

The photoelectric conversion element of the present invention can be produced by a production method including, for example, a step of forming a first electrode on a substrate, a step of applying a composition comprising the polymer compound of the present invention and a solvent onto the first electrode by a coating method to form an active layer, and a step of forming a second electrode on the active layer.

When a hole transport layer is provided, the photoelectric conversion element of the present invention can be produced by a production method including, for example, a step of forming a first electrode on a substrate, a step of forming a hole transport layer on the first electrode, applying a composition comprising the polymer compound of the present invention and a solvent on the hole transport layer by a coating method to form an active layer, and a step of forming a second electrode on the active layer.

(Step of Forming First Electrode)

The first electrode is formed in a predetermined pattern shape on the substrate. The substrate with the first electrode formed thereon may be prepared by obtaining a commercially available structure with a thin film comprising a conductive material formed on a substrate and patterning the thin film comprising the conductive material on the substrate, or by obtaining a substrate with electrodes which have been patterned in advance.

As a matter of course, only the substrate may be prepared in this step to perform the step of forming the first electrode on the substrate.

In this case, the first electrode may be formed by forming a thin film on the substrate by a vacuum deposition method, a sputtering method, an ion plating method, a plating method, or the like using the material of the first electrode as previously described, and patterning the thin film by any suitable method, as necessary.

When an organic material such as polyaniline and a derivative thereof, polythiophene and a derivative thereof, and a nanostructure of a conductive substance (for example, nanoparticles, nanowires, nanotubes) are used as the first electrode material, the first electrode may be formed by applying a coating liquid comprising the organic material (for example, a solution, an emulsion, a suspension), a metal ink, a metal paste or a low melting-point metal in a molten state, etc.

Examples of the coating method for forming the first electrode may include a spin coating method, a casting method, a microgravure coating method, a gravure coating method, a bar coating method, a roll coating method, a wire-bar coating method, a dip coating method, a spray coating method, a screen printing method, a flexographic printing method, an offset printing method, an ink-jet printing method, a dispenser printing method, a nozzle coating method, and a capillary coating method. Among these, a spin coating method, a flexographic printing method, an ink jet printing method, and a dispenser printing method are preferable.

Examples of the solvent of the coating liquid used in forming the first electrode by a coating method may include hydrocarbon solvents (for example, toluene, xylene, mesitylene, tetralin, decalin, bicyclohexyl, n-butylbenzene, sec-butylbenzene, tert-butylbenzene, etc.), halogenated saturated hydrocarbon solvents (for example, carbon tetrachloride, chloroform, dichloromethane, dichloroethane, chlorobutane, bromobutane, chloropentane, bromopentane, chlorohexane, bromohexane, chlorocyclohexane, bromocyclohexane, etc.), halogenated unsaturated hydrocarbons (for example, chlorobenzene, dichlorobenzene, trichlorobenzene, etc.), ether solvents (for example, tetrahydrofuran, tetrahydropyran, etc.), water, alcohols, and the like. Specific examples of the alcohol may include methanol, ethanol, isopropanol, butanol, ethylene glycol, propylene glycol, butoxyethanol, methoxybutanol, and the like. The coating liquid to be used for forming an anode by a coating method may comprise two or more types of solvents, and may comprise two or more types of solvents exemplified as above.

The first electrode may be subjected to a surface treatment such as an ozone UV treatment, a corona treatment, an ultrasonic treatment, etc.

(Step of Forming Hole Transport Layer)

According to one embodiment described above for providing a hole transport layer, the step of forming a hole transport layer is performed. Although the method of forming a hole transport layer is not particularly limited, it is preferable to form the hole transport layer by a coating method from the viewpoint of simplification of production process. When a coating method is used to form a hole injection layer to be joined to the first electrode, the hole transport layer can be formed by, for example, applying a coating liquid which is a composition comprising the material of the hole transport layer described above and a solvent (medium) to the support substrate on the first electrode side on which the first electrode has been formed.

Examples of the method of applying a coating liquid comprising the material of the hole transport layer described above and the solvent are similar to examples and preferred examples of the coating method described above in the method of forming an anode.

The solvent comprised in the coating liquid to form the hole transport layer may include water, alcohols, ketones, hydrocarbons, and the like. Specific examples of the alcohol may include methanol, ethanol, isopropanol, butanol, ethylene glycol, propylene glycol, butoxyethanol, methoxybutanol, and the like. Specific examples of the ketone may include acetone, methyl ethyl ketone, methyl isobutyl ketone, 2-heptanone, and cyclohexanone. Specific examples of the hydrocarbon may include n-pentane, cyclohexane, n-hexane, benzene, toluene, xylene, tetralin, chlorobenzene, ortho-dichlorobenzene, and the like. Two or more types of solvents may be comprised, and two or more types of solvents exemplified as above may be comprised. The solvent is comprised in an amount of preferably 1 time by weight or more and 10,000 times by weight or less, and more preferably 10 times by weight or more and 1,000 times by weight or less, relative to the material of the hole injection layer.

(Step of Forming Active Layer)

The active layer may be produced by any method, the example of which may include a coating method using a coating liquid comprising the polymer compound and a solvent, or a film formation method by vacuum deposition.

It is preferable to form by a coating method because the step can be simplified. After applying the coating liquid by the coating method, it is preferable to further carry out a step of removing the solvent by heating, air drying, vacuum treatment, etc. for the coating film.

The solvent to be comprised in the coating liquid used for the coating method is not particularly limited as long as the solvent dissolves the polymer compound of the present invention. Examples of the solvent may include unsaturated hydrocarbon solvents such as toluene, xylene, mesitylene, tetralin, decalin, bicyclohexyl, n-butylbenzene, sec-butylbenzene, and tert-butylbenzene, halogenated saturated hydrocarbon solvents such as carbon tetrachloride, chloroform, dichloromethane, dichloroethane, chlorobutane, bromobutane, chloropentane, bromopentane, chlorohexane, bromohexane, chlorocyclohexane, and bromocyclohexane, halogenated unsaturated hydrocarbon solvents such as chlorobenzene, dichlorobenzene, and trichlorobenzene, and ether solvents such as tetrahydrofuran and tetrahydropyran. The polymer compound of the present invention can be usually dissolved in the aforementioned solvent in an amount of 0.1% by weight or more.

Examples of the coating method may include a slit coating method, a knife coating method, a spin coating method, a casting method, a microgravure coating method, a gravure coating method, a bar coating method, a roll coating method, a wire-bar coating method, a dip coating method, a spray coating method, a screen printing method, a gravure printing method, a flexographic printing method, an offset printing method, an ink-jet coating method, a dispenser printing method, a nozzle coating method, a capillary coating method, and the like. A slit coating method, a capillary coating method, a gravure coating method, a microgravure coating method, a bar coating method, a knife coating method, a nozzle coating method, an ink-jet coating method, and a spin coating method are preferable.

From the viewpoint of film formation properties, the surface tension of the solvent at 25° C. is preferably more than 15 mN/m, more preferably more than 15 mN/m and less than 100 mN/m, and still more preferably more than 25 mN/m and less than 60 mN/m.

(Step of Forming Second Electrode)

The second electrode can be formed by a vacuum deposition method, a sputtering method, an ion plating method, a plating method, a coating method, and the like.

<Application of Organic Photoelectric Conversion Element>

The organic photoelectric conversion element comprising the polymer compound of the present invention in the active layer can be operated as an organic thin film solar cell with photovoltaic power generated between electrodes by irradiating it with light such as solar light, through a transparent or translucent electrode. A plurality of these organic thin film solar cells integrated can also be used as an organic thin film solar cell module.

The organic photoelectric conversion element can also be used as a solar cell if photovoltaic power is generated between electrodes using solar light obtained through a window and indoor illumination such as fluorescent lamp. The photoelectric conversion elements using the polymer compound of the present invention are considered to be very useful as solar cells.

When the photoelectric conversion element is irradiated with light from a transparent or translucent electrode with or without voltage applied between the electrodes, a photocurrent can flow, whereby the photoelectric conversion element can be operated as an organic optical sensor. A plurality of organic optical sensors integrated can also be used as an organic image sensor.

(Solar Cell Module)

The organic thin film solar cell can have essentially the same module structure as those of conventional solar cell modules. The solar cell module is generally constructed such that a cell is configured on a support substrate of such as a metal or ceramic, and is covered with a filler resin or a protective glass thereover to take in light from the opposite side of the support substrate. The solar cell module may also be constructed such that a cell is configured on a support substrate using a transparent material such as reinforced glass to take in light from the transparent support substrate side. Specifically, module structures called super straight, sub-straight or potting type, substrate integrated module structures used in amorphous silicon solar cells, and the like are known. These module structures may appropriately be selected also for the organic thin film solar cell produced using the polymer compound of the present invention, depending on the intended use, location of use, and environment.

Typical super straight or sub-straight type modules have a structure in which cells are arranged at constant intervals between supporting substrates one or both surfaces of which have been subjected to an antireflection treatment, and the adjacent cells are connected by metal leads or flexible wirings and the electrical current collectors are disposed at its outer edges to take out generated power to the outside. In order to protect the cell and improve current collection efficiency, various types of plastic materials such as ethylene vinyl acetate (EVA) may be used in the form of films or filler resins between the substrate and the cell, depending on the purpose.

In addition, when the module is used in an area where there is little external impact and where there is no need to cover the surface with a hard material, a surface protection layer can be formed of a transparent plastic film, or the above-described filling resin can be cured to impart a protective function to thereby eliminate the support substrate on one side. The periphery of the support substrate is sandwiched with and secured by a metal frame to ensure internal sealing and module rigidity, and a sealing material is used to seal between the support substrate and the frame. When the cells themselves, support substrates, fillers, and sealing materials adopt a flexible material, the solar cells can also be constructed on a curved surface. In the case of a solar cell using a flexible support such as a polymer film, the cell body can be produced by sequentially forming a cell while feeding a roll support, cutting it to a desired size, and sealing the edge with a flexible, moisture-proof material. Module structures called “SCAF” as described in Solar Energy Materials and Solar Cells, 48, pp. 383-391 may also be adopted. In addition, solar cells using flexible substrates can also be used by bonding and fixing them on curved glass, etc.

<Organic Thin Film Transistor>

The polymer compound of the present invention can also be used for an organic thin film transistor. The organic thin film transistor may include an organic thin film transistor having a source electrode, a drain electrode, an organic semiconductor layer (active layer) which provides a current path between electrodes of the source and drain electrodes, and a gate electrode which controls the current rate through the current path, wherein the organic semiconductor layer includes the polymer compound of the present invention. Such an organic thin film transistor may include a field effect type, an electrostatic induction type, and the like. The organic thin film transistor can be used as pixel drive elements to control pixels of, for example, electrophoresis displays, liquid crystal displays, organic electroluminescent displays, etc., and as pixel drive elements to control the uniformity of screen brightness and screen rewrite rates.

Preferably, the field effect type organic thin film transistor includes a source electrode, a drain electrode, an organic semiconductor layer (active layer) which provides a current path between the source electrode and the drain electrode, a gate electrode which controls the current rate through the current path, and an insulating layer disposed between the organic semiconductor layer and the gate electrode.

In particular, the source and drain electrodes are preferably provided to be in contact with the organic semiconductor layer (the active layer), and the gate electrode is provided such that the insulating layer in contact with the organic semiconductor layer is interposed therebetween.

The electrostatic induction type organic thin film transistor preferably has a source electrode, a drain electrode, an organic semiconductor layer (active layer) which provides a current path between the source electrode and the drain electrode, and a gate electrode which controls the current flow rate through the current path, wherein the gate electrode is provided in the organic semiconductor layer. In particular, it is preferable that the source electrode, the drain electrode and the gate electrode disposed in the organic semiconductor layer are provided to be in contact with the organic semiconductor layer. The structure of the gate electrode may be any structure as long as a current path flowing from the source electrode to the drain electrode is formed and the current flow rate through the current path can be controlled by a voltage applied to the gate electrode. Examples thereof may include a comb-shaped electrode.

<Organic Electroluminescent Element>

The polymer compound of the present invention can also be used for organic electroluminescent elements (organic EL elements). The organic EL element has a light-emitting layer between a pair of electrodes, at least one of which is transparent or translucent. In addition to the light-emitting layer, the organic EL element may also include a hole transport layer and an electron transport layer. The polymer compound of the present invention is comprised in any of the layers of the light-emitting layer, hole transport layer, and electron transport layer. The light emitting layer may also comprise a charge transport material (meaning a collective term for electron transport materials and hole transport materials) in addition to the polymer compound of the present invention. The organic EL element may include an element having an anode, a light-emitting layer, and a cathode; an element having an anode, a light-emitting layer, and a cathode and further having an electron transport layer which is located between the cathode and the light-emitting layer and comprises an electron transport material adjacent to the light-emitting layer; an element having an anode, a light-emitting layer, and a cathode and further having a hole transport layer which is located between the anode and the light-emitting layer and comprises a hole transport material adjacent to the light emitting layer; an element having an anode, a hole transport layer, a light-emitting layer, an electron transport layer, and a cathode; and the like.

<OFET Sensor>

The polymer compound of the present invention may also be used for the production of OFET sensors. The OFET sensor of the present invention uses an organic field effect transistor as a signal conversion element which converts an input signal into an electrical signal as an output. In the OFET sensor of the present invention, a sensitive function or selective function is provided into any of the structures of metals, insulating films, and organic semiconductor layers. Examples of the OFET sensor of the present invention may include a biosensor, a gas sensor, an ion sensor, and a humidity sensor.

The biosensor includes a substrate and an organic thin film transistor disposed on the substrate. The organic thin film transistor has an organic semiconductor layer, a source region and a drain region provided to be in contact with the organic semiconductor, a channel region in the organic semiconductor layer between the source region and the drain region, a gate electrode capable of applying an electric field to the channel region, and a gate insulating film disposed between the channel region and the gate electrode. The organic thin film transistor has a probe (sensitive region) which interacts specifically with a target material in the channel region and/or gate insulating film, and thus functions as a biosensor by causing a change in the properties of the probe when the target material changes in concentration.

Examples of a technique for detecting a target substance in a test sample may include biosensors in which biomolecules such as nucleic acids and proteins, or artificially synthesized functional groups, are immobilized as probes on the surface of a solid support.

In this method, the target material is captured on the surface of the solid support using specific affinities of the biomolecule such as complementary nucleic acid strand interactions, antigen-antibody reaction interactions, enzyme-substrate reaction interactions, receptor-ligand interactions, etc. Therefore, a substance with a specific affinity for the target substance is selected as a probe.

The probe is immobilized on the surface of the solid support in a manner appropriate to the type of probe and the type of solid support. The probe may also be synthesized on a solid support surface (for example, a method of synthesizing a probe by a nucleic acid extension reaction). In either case, a probe-target material complex is formed on the surface of the solid support by allowing the test sample to be brought into contact with the surface of the solid support on which the probe has been immobilized and culturing under appropriate conditions. The channel region and/or the gate insulating film itself possessed by the organic thin film transistor may serve as a probe.

The gas sensor includes a substrate and an organic thin film transistor disposed on the substrate. The organic thin film transistor has an organic semiconductor layer, a source region and a drain region disposed to be in contact with the organic semiconductor, a channel region in the semiconductor layer between the source region and the drain region, a gate electrode capable of applying an electric field to the channel region, and a gate insulating film disposed between the channel region and the gate electrode. In the organic thin film transistor, the channel region and/or the gate insulating film functions as a gas sensitive part. When the sensed gas is adsorbed by and desorbed from the gas sensitive part, the characteristic change (conductivity, dielectric constant, etc.) of the gas sensitive part occurs, and thus the organic thin film transistor functions as a gas sensor.

Examples of the gas to be sensed may include an electron-accepting gas and an electron-donating gas. Examples of the electron-accepting gas may include halogen gases such as F₂ and Cl₂; nitrogen oxide gases; sulfur oxide gases; and organic acid gases such as acetic acid. Examples of the electron-donating gas may include ammonia gas; amine gases such as aniline; carbon monoxide gas; and hydrogen gas.

The polymer compound of the present invention may also be used for the production of pressure sensors. The pressure sensor of the present invention includes a substrate and an organic thin film transistor disposed on the substrate. The organic thin film transistor has an organic semiconductor layer, a source region and a drain region disposed to be in contact with the organic semiconductor, a channel region in the organic semiconductor layer between the source region and the drain region, a gate electrode capable of applying an electric field to the channel region, and a gate insulating film disposed between the channel region and the gate electrode. In the organic thin film transistor, the channel region and/or the gate insulating film functions as a pressure sensitive part. When the pressure sensitive part senses pressure, characteristic change of the pressure sensitive part occurs, and the organic thin film transistor functions as a pressure sensitive sensor.

When the gate insulating film functions as a pressure sensitive part, the gate insulating film preferably comprises an organic material because the organic material is more flexible and more elastic than the inorganic material.

If the channel region functions as the pressure sensitive part, the organic thin film transistor may further have an oriented layer to enhance the crystallinity of the organic semiconductor comprised in the channel region. Examples of the oriented layer may include a monomolecular film formed on a gate insulating film using a silane coupling agent such as hexamethyldisilazane.

The polymer compound of the present invention may also be used for the production of a conductivity modulation type sensor. The conductivity modulation type sensor of the present invention uses a conductivity measuring element as a signal conversion element which converts an input signal into an electrical signal as an output. In the conductivity modulation type sensor of the present invention, a sensitive function or selective function in response to an input of a sensor object is provided into the film comprising the composition or the polymer compound of the present invention or into a coating of the film comprising the composition or the polymer compound of the present invention. The conductivity modulation type sensor of the present invention detects the input of the sensor object as a change in the conductivity of the composition or the polymer compound of the present invention. Examples of the conductivity modulation type sensor of the present invention may include a biosensor, a gas sensor, an ion sensor, and a humidity sensor.

The polymer compound of the present invention can also be used for the production of amplification circuits including an organic field effect transistor as an amplification circuit for amplifying an output signal from a variety of sensors, including separately formed biosensors, gas sensors, ion sensors, humidity sensors, pressure sensors, and the like.

The polymer compound of the present invention may also be used for the production of sensor arrays including a plurality of sensors including biosensors, gas sensors, ion sensors, humidity sensors, pressure sensors, and the like.

The polymer compound of the present invention may also be used for the production of sensor arrays with an amplification circuit including an organic field effect transistor as an amplification circuit for independently amplifying an output signal from each sensor, including multiple sensors including separately formed biosensors, gas sensors, ion sensors, humidity sensors, pressure sensors, and the like.

<Organic Optical Sensor>

The organic photoelectric conversion element of the present invention can be operated as an organic optical sensor through which photocurrent flows by irradiating it with light through a transparent or translucent electrode with voltage applied between the electrodes. Furthermore, the organic photoelectric conversion element of the present invention can be used as an organic image sensor including: the organic optical sensor as a light receiving part, a driver circuit which detects the signal current generated by the organic optical sensor and reads the signal charge; and a wiring connecting the organic optical sensor and the driver circuit. The organic optical sensor can be used while a color filter is equipped on the side of the incident light surface in order to provide color selectivity of light to be detected. Alternatively, plural types of organic optical sensors having light absorption characteristics with high selectivity to each of the three primary colors of light can be also used. The drive circuit can be composed of an IC chip formed of a transistor using single crystal silicon, or a thin film transistor using polycrystalline silicon, amorphous silicon, a compound semiconductor such as cadmium selenide, and a conjugated organic compound semiconductor such as pentacene, and the like. The organic image sensors are expected to offer advantages such as lower production costs and smaller installation area compared to existing image sensors using charge-coupled devices (CCDs) and complementary metal-oxide-semiconductors (CMOS) as photographic elements such as scanners, digital cameras, and digital videos. Due to the diversity of conjugated compounds, organic optical sensors with various light sensitivity characteristics can be used, thus providing organic image sensors with performance depending on the application. For example, organic optical sensors including the polymer compound of the present invention can be applied to vein authentication, fingerprint authentication, pulse oximeters, motion sensors, and X-ray image panels.

### EXAMPLES

Hereinafter, the present invention will be specifically described by illustrating Examples. However, the present invention is not limited to the following Examples.

(Measurement of Number-Average Molecular Weight

And Weight-Average Molecular Weight)

In Examples, the polystyrene-equivalent number-average molecular weight (Mn) and the polystyrene-equivalent weight-average molecular weight (Mw) of the polymer compound were determined by gel permeation chromatography (GPC) (manufactured by Shimadzu Corporation, trade name: LC-10Avp). The polymer compound to be measured was dissolved in tetrahydrofuran at a concentration of about 0.5% by weight, and 30 μL of the obtained solution was injected into GPC. Tetrahydrofuran was used as the mobile phase of GPC and flowed at a flow rate of 0.6 mL/min. Two TSKgel SuperHM-H columns (manufactured by Tosoh Corporation) and one TSKgel SuperH2000 column (manufactured by Tosoh Corporation) were connected in series. A differential refractive index detector (manufactured by Shimadzu Corporation, trade name: RID-10A) was used as the detector.

### Example 1

### (Synthesis of Polymer Compound P1)

[chemical structure]

After the inside of a 200 mL separable flask equipped with a reflux tube was set in a nitrogen atmosphere, 666 mg (0.950 mmol) of a compound 1, 44.9 mg (0.050 mmol) of a compound 2, 388 mg (1.00 mmol) of a compound 3, 23.2 mg (0.0800 mml) of tri-tert-butylphosphonium tetrafluoroborate ([P(t-Bu)₃H]BF₄), 25.0 ml of tetrahydrofuran, and 25.0 ml of chlorobenzene were placed therein to form a uniform solution. After nitrogen gas was bubbled for 30 minutes, 18.3 mg (0.0200 mmol) of tris(dibenzylideneacetone)dipalladium(0) (Pd₂(dba)₃) and 3.30 mL of an aqueous K₃PO₄ solution were added, and the resulting solution was heated to 70° C. and stirred for 30 minutes at 70° C. Thereafter, 25.0 mL of ortho-dichlorobenzene and 38.0 mL of water were added thereto to stop the reaction. After heating and stirring at 70° C. for additional 10 minutes, the aqueous layer was removed. The obtained organic layer was washed once with 38 mL of an aqueous acetic acid solution and twice with 38 mL of water, and the obtained solution was poured into acetone to precipitate a polymer, followed by filtration. The resulting solid was dissolved in 115 mL of ortho-dichlorobenzene and passed through an alumina/silica gel column. The obtained solution was poured into methanol to precipitate a polymer, and then filtered. The obtained solid was dried and purified to obtain 322 mg of a polymer P1. Hereinafter, this polymer is referred to as a polymer compound P1. The molecular weight (polystyrene equivalent) of the polymer compound P1 measured by GPC was Mn.=34,000 and Mw.=245,000.

### Example 2

### (Synthesis of Polymer Compound P2)

[chemical structure]

After the inside of a 200 mL separable flask equipped with a reflux tube was set in a nitrogen atmosphere, 746 mg (0.950 mmol) of a compound 4, 44.9 mg (0.050 mmol) of the compound 2, 388 mg (1.00 mmol) of the compound 3, 23.2 mg (0.0800 mml) of tri-tert-butylphosphonium tetrafluoroborate ([P(t-Bu)₃H]BF₄), 25.0 ml of tetrahydrofuran, and 25.0 ml of chlorobenzene were placed therein to form a uniform solution. After nitrogen gas was bubbled for 30 minutes, 18.3 mg (0.0200 mmol) of tris(dibenzylideneacetone)dipalladium(0) (Pd₂(dba)₃) and 3.30 mL of an aqueous K₃PO₄ solution were added, and the resulting solution was heated to 70° C. and stirred for 30 minutes at 70° C. Thereafter, 25.0 mL of ortho-dichlorobenzene and 38.0 mL of water were added thereto to stop the reaction. After heating and stirring at 70° C. for additional 10 minutes, the aqueous layer was removed. The obtained organic layer was washed once with 38 mL of an aqueous acetic acid solution and twice with 38 mL of water, and the obtained solution was poured into acetone to precipitate a polymer, followed by filtration. The resulting solid was dissolved in 115 mL of ortho-dichlorobenzene and passed through an alumina/silica gel column. The obtained solution was poured into methanol to precipitate a polymer, and then filtered. The obtained solid was dried and purified to obtain 467 mg of a polymer P2. Hereinafter, this polymer is referred to as a polymer compound P2. The molecular weight (polystyrene equivalent) of the polymer compound P2 measured by GPC was Mn.=88,000 and Mw.=496,000.

### Example 3

### (Synthesis of Polymer Compound P3)

[chemical structure]

After the inside of a 200 mL separable flask equipped with a reflux tube was set in a nitrogen atmosphere, 706 mg (0.900 mmol) of the compound 4, 89.7 mg (0.100 mmol) of the compound 2, 388 mg (1.00 mmol) of the compound 3, 23.2 mg (0.0800 mml) of tri-tert-butylphosphonium tetrafluoroborate ([P(t-Bu)₃H]BF₄), 25.0 ml of tetrahydrofuran, and 25.0 ml of chlorobenzene were placed therein to form a uniform solution. After nitrogen gas was bubbled for 30 minutes, 18.3 mg (0.0200 mmol) of tris(dibenzylideneacetone)dipalladium(0) (Pd₂(dba)₃) and 3.30 mL of an aqueous K₃PO₄ solution were added, and the resulting solution was heated to 70° C. and stirred for 30 minutes at 70° C. Thereafter, 25.0 mL of ortho-dichlorobenzene and 38.0 mL of water were added thereto to stop the reaction. After heating and stirring at 70° C. for additional 10 minutes, the aqueous layer was removed. The obtained organic layer was washed once with 38 mL of an aqueous acetic acid solution and twice with 38 mL of water, and the obtained solution was poured into acetone to precipitate a polymer, followed by filtration. The resulting solid was dissolved in 115 mL of ortho-dichlorobenzene and passed through an alumina/silica gel column. The obtained solution was poured into methanol to precipitate a polymer, and then filtered. The obtained solid was dried and purified to obtain 385 mg of a polymer P3. Hereinafter, this polymer is referred to as a polymer compound P3. The molecular weight (polystyrene equivalent) of the polymer compound P3 measured by GPC was Mn.=73,000 and Mw.=545,000.

### Example 4

### (Synthesis of Polymer Compound P4)

[chemical structure]

After the inside of a 200 mL separable flask equipped with a reflux tube was set in a nitrogen atmosphere, 350 mg (0.500 mmol) of the compound 1, 392 mg (0.500 mmol) of the compound 4, 392 mg (1.00 mmol) of a compound 5, 23.2 mg (0.0800 mml) of tri-tert-butylphosphonium tetrafluoroborate ([P(t-Bu)₃H]BF₄), 25.0 ml of tetrahydrofuran, and 25.0 mL of chlorobenzene were placed therein to form a uniform solution. After nitrogen gas was bubbled for 30 minutes, 18.3 mg (0.0200 mmol) of tris(dibenzylideneacetone)dipalladium (0) (Pd₂(dba)₃) and 3.30 mL of an aqueous K₃PO₄ solution were added, and the resulting solution was heated to 70° C. and stirred for 30 minutes at 70° C. Thereafter, 25.0 mL of ortho-dichlorobenzene and 38.0 mL of water were added thereto to stop the reaction. After heating and stirring at 70° C. for additional 10 minutes, the aqueous layer was removed. The obtained organic layer was washed once with 38 mL of an aqueous acetic acid solution and twice with 38 mL of water, and the obtained solution was poured into acetone to precipitate a polymer, followed by filtration. The resulting solid was dissolved in 115 mL of ortho-dichlorobenzene and passed through an alumina/silica gel column. The obtained solution was poured into methanol to precipitate a polymer, and then filtered. The obtained solid was dried and purified to obtain 397 mg of a polymer P4. Hereinafter, this polymer is referred to as a polymer compound P4. The molecular weight (polystyrene equivalent) of the polymer compound P4 measured by GPC was Mn.=71,000 and Mw.=350,000.

### Example 5

### (Synthesis of Polymer Compound P5)

[chemical structure]

After the inside of a 200 mL separable flask equipped with a reflux tube was set in a nitrogen atmosphere, 210 mg (0.300 mmol) of the compound 1, 549 mg (0.700 mmol) of the compound 4, 392 mg (1.00 mmol) of the compound 5, 23.2 mg (0.0800 mml) of tri-tert-butylphosphonium tetrafluoroborate ([P(t-Bu)₃H]BF₄), 25.0 ml of tetrahydrofuran, and 25.0 ml of chlorobenzene were placed therein to form a uniform solution. After nitrogen gas was bubbled for 30 minutes, 18.3 mg (0.0200 mmol) of tris(dibenzylideneacetone)dipalladium(0) (Pd₂(dba)₃) and 3.30 mL of an aqueous K₃PO₄ solution were added, and the resulting solution was heated to 70° C. and stirred for 30 minutes at 70° C. Thereafter, 25.0 mL of ortho-dichlorobenzene and 38.0 mL of water were added thereto to stop the reaction. After heating and stirring at 70° C. for additional 10 minutes, the aqueous layer was removed. The obtained organic layer was washed once with 38 mL of an aqueous acetic acid solution and twice with 38 mL of water, and the obtained solution was poured into acetone to precipitate a polymer, followed by filtration. The resulting solid was dissolved in 115 mL of ortho-dichlorobenzene and passed through an alumina/silica gel column. The obtained solution was poured into methanol to precipitate a polymer, and then filtered. The obtained solid was dried and purified to obtain 428 mg of a polymer P5. Hereinafter, this polymer is referred to as a polymer compound P5. The molecular weight (polystyrene equivalent) of the polymer compound P5 measured by GPC was Mn.=109,000 and Mw.=670,000.

### Example 6

### (Synthesis of Polymer Compound P6)

[chemical structure]

After the inside of a 200 mL separable flask equipped with a reflux tube was set in a nitrogen atmosphere, 631 mg (0.900 mmol) of the compound 1, 89.7 mg (0.100 mmol) of the compound 2, 392 mg (1.00 mmol) of the compound 5, 23.2 mg (0.0800 mml) of tri-tert-butylphosphonium tetrafluoroborate ([P(t-Bu)₃H]BF₄), 25.0 ml of tetrahydrofuran, and 25.0 ml of chlorobenzene were placed therein to form a uniform solution. After nitrogen gas was bubbled for 30 minutes, 18.3 mg (0.0200 mmol) of tris(dibenzylideneacetone)dipalladium(0) (Pd₂(dba)₃) and 3.30 mL of an aqueous K₃PO₄ solution were added, and the resulting solution was heated to 70° C. and stirred for 30 minutes at 70° C. Thereafter, 25.0 mL of ortho-dichlorobenzene and 38.0 mL of water were added thereto to stop the reaction. After heating and stirring at 70° C. for additional 10 minutes, the aqueous layer was removed. The obtained organic layer was washed once with 38 mL of an aqueous acetic acid solution and twice with 38 mL of water, and the obtained solution was poured into acetone to precipitate a polymer, followed by filtration. The resulting solid was dissolved in 115 mL of ortho-dichlorobenzene and passed through an alumina/silica gel column. The obtained solution was poured into methanol to precipitate a polymer, and then filtered. The obtained solid was dried and purified to obtain 468 mg of a polymer P6. Hereinafter, this polymer is referred to as a polymer compound P6. The molecular weight (polystyrene equivalent) of the polymer compound P6 measured by GPC was Mn.=65,000 and Mw.=336,000.

### Example 7

### (Synthesis of Polymer Compound P7)

[chemical structure]

After the inside of a 200 mL separable flask equipped with a reflux tube was set in a nitrogen atmosphere, 746 mg (0.950 mmol) of the compound 4, 44.9 mg (0.050 mmol) of the compound 2, 392 mg (1.00 mmol) of the compound 5, 23.2 mg (0.0800 mml) of tri-tert-butylphosphonium tetrafluoroborate ([P(t-Bu)₃H]BF₄), 25.0 ml of tetrahydrofuran, and 25.0 ml of chlorobenzene were placed therein to form a uniform solution. After nitrogen gas was bubbled for 30 minutes, 18.3 mg (0.0200 mmol) of tris(dibenzylideneacetone)dipalladium(0) (Pd₂(dba)₃) and 3.30 mL of an aqueous K₃PO₄ solution were added, and the resulting solution was heated to 70° C. and stirred for 30 minutes at 70° C. Thereafter, 25.0 mL of ortho-dichlorobenzene and 38.0 mL of water were added thereto to stop the reaction. After heating and stirring at 70° C. for additional 10 minutes, the aqueous layer was removed. The obtained organic layer was washed once with 38 mL of an aqueous acetic acid solution and twice with 38 mL of water, and the obtained solution was poured into acetone to precipitate a polymer, followed by filtration. The resulting solid was dissolved in 115 mL of ortho-dichlorobenzene and passed through an alumina/silica gel column. The obtained solution was poured into methanol to precipitate a polymer, and then filtered. The obtained solid was dried and purified to obtain 584 mg of a polymer P7. Hereinafter, this polymer is referred to as a polymer compound P7. The molecular weight (polystyrene equivalent) of the polymer compound P7 measured by GPC was Mn.=107,000 and Mw.=663,000.

### Example 8

### (Synthesis of Polymer Compound P8)

[chemical structure]

After the inside of a 200 mL separable flask equipped with a reflux tube was set in a nitrogen atmosphere, 315 mg (0.450 mmol) of the compound 1, 353 mg (0.450 mmol) of the compound 4, 89.7 mg (0.100 mmol) of the compound 2, 392 mg (1.00 mmol) of the compound 5, 23.2 mg (0.0800 mml) of tri-tert-butylphosphonium tetrafluoroborate ([P(t-Bu)₃H]BF₄), 25.0 ml of tetrahydrofuran, and 25.0 ml of chlorobenzene were placed therein to form a uniform solution. After nitrogen gas was bubbled for 30 minutes, 18.3 mg (0.0200 mmol) of tris(dibenzylideneacetone)dipalladium(0) (Pd₂(dba)₃) and 3.30 mL of an aqueous K₃PO₄ solution were added, and the resulting solution was heated to 70° C. and stirred for 30 minutes at 70° C. Thereafter, 25.0 mL of ortho-dichlorobenzene and 38.0 mL of water were added thereto to stop the reaction. After heating and stirring at 70° C. for additional 10 minutes, the aqueous layer was removed. The obtained organic layer was washed once with 38 mL of an aqueous acetic acid solution and twice with 38 mL of water, and the obtained solution was poured into acetone to precipitate a polymer, followed by filtration. The resulting solid was dissolved in 115 mL of ortho-dichlorobenzene and passed through an alumina/silica gel column. The obtained solution was poured into methanol to precipitate a polymer, and then filtered. The obtained solid was dried and purified to obtain 287 mg of a polymer P8. Hereinafter, this polymer is referred to as a polymer compound P8. The molecular weight (polystyrene equivalent) of the polymer compound P8 measured by GPC was Mn.=60,000 and Mw.=456,000.

### Synthesis Example 1

### (Synthesis of Polymer Compound PI)

[chemical structure]

Under nitrogen atmosphere, after the inside of a 200 mL separable flask equipped with a reflux tube was set in a nitrogen atmosphere, 785 mg (1.00 mmol) of the compound 4, 388 mg (1.00 mmol) of the compound 3, 23.2 mg (0.0800 mml) of tri-tert-butylphosphonium tetrafluoroborate ([P(t-Bu)₃H]BF₄), 25.0 ml of tetrahydrofuran, and 25.0 ml of chlorobenzene were placed therein to form a uniform solution. After nitrogen gas was bubbled for 30 minutes, 18.3 mg (0.0200 mmol) of tris(dibenzylideneacetone)dipalladium(0) (Pd₂(dba)₃) and 3.30 mL of an aqueous K₃PO₄ solution were added, and the resulting solution was heated to 70° C. and stirred for 30 minutes at 70° C. Thereafter, 25.0 mL of ortho-dichlorobenzene and 38.0 mL of water were added thereto to stop the reaction. After heating and stirring at 70° C. for additional 10 minutes, the aqueous layer was removed. The obtained organic layer was washed once with 38 mL of an aqueous acetic acid solution and twice with 38 mL of water, and the obtained solution was poured into acetone to precipitate a polymer, followed by filtration. The resulting solid was dissolved in 115 mL of ortho-dichlorobenzene and passed through an alumina/silica gel column. The obtained solution was poured into methanol to precipitate a polymer, and then filtered. The obtained solid was dried and purified to obtain 405 mg of a polymer PI. Hereinafter, this polymer is referred to as a polymer compound PI. The molecular weight (polystyrene equivalent) of the polymer compound PI measured by GPC was Mn.=40,000 and Mw.=126,000.

### Synthesis Example 2

### (Synthesis of Polymer Compound PII)

[chemical structure]

Under nitrogen atmosphere, after the inside of a 200 mL separable flask equipped with a reflux tube was set in a nitrogen atmosphere, 706 mg (1.00 mmol) of the compound 1, 388 mg (1.00 mmol) of the compound 3, 23.2 mg (0.0800 mml) of tri-tert-butylphosphonium tetrafluoroborate ([P(t-Bu)₃H]BF₄), 25.0 ml of tetrahydrofuran, and 25.0 ml of chlorobenzene were placed therein to form a uniform solution. After nitrogen gas was bubbled for 30 minutes, 18.3 mg (0.0200 mmol) of tris(dibenzylideneacetone)dipalladium(0) (Pd₂(dba)₃) and 3.30 mL of an aqueous K₃PO₄ solution were added, and the resulting solution was heated to 70° C. and stirred for 30 minutes at 70° C. Thereafter, 25.0 mL of ortho-dichlorobenzene and 38.0 mL of water were added thereto to stop the reaction. After heating and stirring at 70° C. for additional 10 minutes, the aqueous layer was removed. The obtained organic layer was washed once with 38 mL of an aqueous acetic acid solution and twice with 38 mL of water, and the obtained solution was poured into acetone to precipitate a polymer, followed by filtration. The resulting solid was dissolved in 115 mL of ortho-dichlorobenzene and passed through an alumina/silica gel column. The obtained solution was poured into methanol to precipitate a polymer, and then filtered. The obtained solid was dried and purified to obtain 419 mg of a polymer PII. Hereinafter, this polymer is referred to as a polymer compound PII. The molecular weight (polystyrene equivalent) of the polymer compound PII measured by GPC was Mn.=38,000 and Mw.=203,000.

### Synthesis Example 3

### (Synthesis of Polymer Compound PIII)

[chemical structure]

Under nitrogen atmosphere, after the inside of a 200 mL separable flask equipped with a reflux tube was set in a nitrogen atmosphere, 897 mg (1.00 mmol) of the compound 2, 388 mg (1.00 mmol) of the compound 3, 23.2 mg (0.0800 mml) of tri-tert-butylphosphonium tetrafluoroborate ([P(t-Bu)₃H]BF₄), 25.0 ml of tetrahydrofuran, and 25.0 ml of chlorobenzene were placed therein to form a uniform solution. After nitrogen gas was bubbled for 30 minutes, 18.3 mg (0.0200 mmol) of tris(dibenzylideneacetone)dipalladium(0) (Pd₂(dba)₃) and 3.30 mL of an aqueous K₃PO₄ solution were added, and the resulting solution was heated to 70° C. and stirred for 30 minutes at 70° C. Thereafter, 25.0 mL of ortho-dichlorobenzene and 38.0 mL of water were added thereto to stop the reaction. After heating and stirring at 70° C. for additional 10 minutes, the aqueous layer was removed. The obtained organic layer was washed once with 38 mL of an aqueous acetic acid solution and twice with 38 mL of water, and the obtained solution was poured into acetone to precipitate a polymer, followed by filtration. The resulting solid was dissolved in 115 mL of ortho-dichlorobenzene and passed through an alumina/silica gel column. The obtained solution was poured into methanol to precipitate a polymer, and then filtered. The obtained solid was dried and purified to obtain 453 mg of a polymer PIII. Hereinafter, this polymer is referred to as a polymer compound PIII. The molecular weight (polystyrene equivalent) of the polymer compound PIII measured by GPC was Mn.=36,000 and Mw.=106,000.

### Synthesis Example 4

### (Synthesis of Polymer Compound PIV)

[chemical structure]

Under nitrogen atmosphere, after the inside of a 200 mL separable flask equipped with a reflux tube was set in a nitrogen atmosphere, 785 mg (1.00 mmol) of the compound 4, 392 mg (1.00 mmol) of the compound 5, 23.2 mg (0.0800 mml) of tri-tert-butylphosphonium tetrafluoroborate ([P(t-Bu)₃H]BF₄), 25.0 ml of tetrahydrofuran, and 25.0 ml of chlorobenzene were placed therein to form a uniform solution. After nitrogen gas was bubbled for 30 minutes, 18.3 mg (0.0200 mmol) of tris(dibenzylideneacetone)dipalladium(0) (Pd₂(dba)₃) and 3.30 mL of an aqueous K₃PO₄ solution were added, and the resulting solution was heated to 70° C. and stirred for 30 minutes at 70° C. Thereafter, 25.0 mL of ortho-dichlorobenzene and 38.0 mL of water were added thereto to stop the reaction. After heating and stirring at 70° C. for additional 10 minutes, the aqueous layer was removed. The obtained organic layer was washed once with 38 mL of an aqueous acetic acid solution and twice with 38 mL of water, and the obtained solution was poured into acetone to precipitate a polymer, followed by filtration. The resulting solid was dissolved in 115 mL of ortho-dichlorobenzene and passed through an alumina/silica gel column. The obtained solution was poured into methanol to precipitate a polymer, and then filtered. The obtained solid was dried and purified to obtain 700 mg of a polymer PIV. Hereinafter, this polymer is referred to as a polymer compound PIV. The molecular weight (polystyrene equivalent) of the polymer compound PIV measured by GPC was Mn.=64,000 and Mw.=202,000.

### Synthesis Example 5

### (Synthesis of Polymer Compound PV)

[chemical structure]

Under nitrogen atmosphere, after the inside of a 200 mL separable flask equipped with a reflux tube was set in a nitrogen atmosphere, 706 mg (1.00 mmol) of the compound 1, 392 mg (1.00 mmol) of the compound 5, 23.2 mg (0.0800 mml) of tri-tert-butylphosphonium tetrafluoroborate ([P(t-Bu)₃H]BF₄), 25.0 ml of tetrahydrofuran, and 25.0 ml of chlorobenzene were placed therein to form a uniform solution. After nitrogen gas was bubbled for 30 minutes, 18.3 mg (0.0200 mmol) of tris(dibenzylideneacetone)dipalladium(0) (Pd₂(dba)₃) and 3.30 mL of an aqueous K₃PO₄ solution were added, and the resulting solution was heated to 70° C. and stirred for 30 minutes at 70° C. Thereafter, 25.0 mL of ortho-dichlorobenzene and 38.0 mL of water were added thereto to stop the reaction. After heating and stirring at 70° C. for additional 10 minutes, the aqueous layer was removed. The organic layer was washed once with 38 mL of an aqueous acetic acid solution and twice with 38 mL of water, and the obtained solution was poured into acetone to precipitate a polymer, followed by filtration. The resulting solid was dissolved in 115 mL of ortho-dichlorobenzene and passed through an alumina/silica gel column. The obtained solution was poured into methanol to precipitate a polymer, and then filtered. The obtained solid was dried and purified to obtain 428 mg of a polymer PV. Hereinafter, this polymer is referred to as a polymer compound PV. The molecular weight (polystyrene equivalent) of the polymer compound PV measured by GPC was Mn.=91,000 and Mw.=421,000.

### Example 9

### (Production And Evaluation of Composition Comprising Solvent And Organic Photoelectric Conversion Element)

A glass substrate having an ITO film with a 150 nm thickness deposited by a sputtering method was subjected to an ozone-UV treatment to perform a surface treatment. Next, as a hole transport material, PEDOT-PSS (AI4083) (manufactured by Heraeus Co., Ltd., product name: CLEVIOS P V P AI 4083) was applied onto the ITO film by spin coating, and was heated at 120° C. for 10 minutes in the atmosphere to produce a hole transport layer having a thickness of about 40 nm. Next, the polymer compound P1 as a p-type semiconductor material and a fullerene derivative C60-PCBM (phenyl 61-butyric acid methyl ester: manufactured by Frontier Carbon Co., Ltd., product name: nanom spectra E100, hereinafter C60-PCBM used was the same product) as an n-type semiconductor material were weighed so that the ratio of the weight of C60PCBM to the weight of the polymer compound P1 was 2, and the mixture was heated and stirred at 50° C. for 15 hours using ortho-dichlorobenzene as a solvent to produce a composition comprising the polymer compound P1, C60PCBM, and ortho-dichlorobenzene. The sum of the weight of the polymer compound P1 and the weight of the C60-PCBM, relative to the weight of the composition, was 1.5% by weight. The composition was applied onto the hole transport layer by spin coating to produce an active layer comprising the polymer compound P1. The thickness was about 100 nm. Thereafter, calcium was vapor-deposited on the active layer by a vacuum deposition machine to have a thickness of 4 nm, and then silver was vapor-deposited to have a thickness of 450 nm to produce an organic photoelectric conversion element. The shape of the organic photoelectric conversion element was a square of 2 mm×2 mm. In order to evaluate the performance of the obtained organic photoelectric conversion element as an organic thin film solar cell, constant light was irradiated using a solar simulator (manufactured by Bunkoukeiki Co., Ltd., trade name: OTENTO-SUNII: AM1.5G filter, irradiance 100 mW/cm²) to determine the value of fill factor. The value of fill factor was 0.690.

### Example 10

### (Production And Evaluation of Composition Comprising Solvent And Organic Photoelectric Conversion Element)

An organic photoelectric conversion element was produced and the value of fill factor was determined in the same manner as that in Example 9 except that the polymer compound P2 was used instead of the polymer compound P1. The value of fill factor was 0.670.

### Example 11

### (Production And Evaluation of Composition Comprising Solvent And Organic Photoelectric Conversion Element)

An organic photoelectric conversion element was produced and the value of fill factor was determined in the same manner as that in Example 9 except that the polymer compound P3 was used instead of the polymer compound P1. The value of fill factor was 0.670.

### Comparative Example 1

### (Production And Evaluation of Composition Comprising Solvent And Organic Photoelectric Conversion Element)

An organic photoelectric conversion element was produced and the value of fill factor was determined in the same manner as that in Example 9 except that the polymer compound PI was used instead of the polymer compound P1. The value of fill factor was 0.610.

### Comparative Example 2

### (Production And Evaluation of Composition Comprising Solvent And Organic Photoelectric Conversion Element)

An organic photoelectric conversion element was produced and the value of fill factor was determined in the same manner as that in Example 9 except that the polymer compound PII was used instead of the polymer compound P1. The value of fill factor was 0.520.

### Comparative Example 3

### (Production And Evaluation of Composition Comprising Solvent And Organic Photoelectric Conversion Element)

An organic photoelectric conversion element was produced and the value of fill factor was determined in the same manner as that in Example 9 except that the polymer compound PIII was used instead of the polymer compound P1. The value of fill factor was 0.450.

The organic photoelectric conversion elements of Examples 9 to 11 had high values of fill factor compared to the organic photoelectric conversion elements of Comparative Examples 1 to 3. The results summarizing the values are shown in the following Table 1.

TABLE 1

| | Polymer compound | |
|---|---|---|
| | (compounds used for | Fill |
| | polymerization) | factor |
| Example 9 | P1 (compounds 1, 2, 3) | 0.690 |
| Example 10 | P2 (compounds 4, 2, 3) | 0.670 |
| Example 11 | P3 (compounds 4, 2, 3) | 0.670 |
| Comparative | PI (compounds 4, 3) | 0.610 |
| Example 1 | | |
| Comparative | PII (compounds 1, 3) | 0.520 |
| Example 2 | | |
| Comparative | PIII (compounds 2, 3) | 0.450 |
| Example 3 | | |

### Example 12

### (Production And Evaluation of Composition Comprising Solvent And Organic Photoelectric Conversion Element)

An organic photoelectric conversion element was produced and the value of fill factor was determined in the same manner as that in Example 9 except that the polymer compound P4 was used instead of the polymer compound P1. The value of fill factor was 0.710.

### Example 13

### (Production And Evaluation of Composition Comprising Solvent And Organic Photoelectric Conversion Element)

An organic photoelectric conversion element was produced and the value of fill factor was determined in the same manner as that in Example 9 except that the polymer compound P5 was used instead of the polymer compound P1. The value of fill factor was 0.705.

### Example 14

### (Production And Evaluation of Composition Comprising Solvent And Organic Photoelectric Conversion Element)

An organic photoelectric conversion element was produced and the value of fill factor was determined in the same manner as that in Example 9 except that the polymer compound P6 was used instead of the polymer compound P1. The value of fill factor was 0.690.

### Example 15

### (Production And Evaluation of Composition Comprising Solvent And Organic Photoelectric Conversion Element)

An organic photoelectric conversion element was produced and the value of fill factor was determined in the same manner as that in Example 9 except that the polymer compound P7 was used instead of the polymer compound P1. The value of fill factor was 0.700.

### Example 16

### (Production And Evaluation of Composition Comprising Solvent And Organic Photoelectric Conversion Element)

An organic photoelectric conversion element was produced and the value of fill factor was determined in the same manner as that in Example 9 except that the polymer compound P8 was used instead of the polymer compound P1. The value of fill factor was 0.690.

### Comparative Example 4

### (Production And Evaluation of Composition Comprising Solvent And Organic Photoelectric Conversion Element)

An organic photoelectric conversion element was produced and the value of fill factor was determined in the same manner as that in Example 9 except that the polymer compound PIV was used instead of the polymer compound P1. The value of fill factor was 0.525.

### Comparative Example 5

### (Production And Evaluation of Composition Comprising Solvent And Organic Photoelectric Conversion Element)

An organic photoelectric conversion element was produced and the value of fill factor was determined in the same manner as that in Example 9 except that the polymer compound PV was used instead of the polymer compound P1. The value of fill factor was 0.600.

The organic photoelectric conversion elements of Examples 12 to 16 had high values of fill factor compared to the organic photoelectric conversion elements of Comparative Examples 4 and 5. The results summarizing the values are shown in the following Table 2.

TABLE 2

| | Polymer compound | |
|---|---|---|
| | (compounds used | Fill |
| | for polymerization) | factor |
| Example 12 | P4 (compounds 1, 4, 5) | 0.710 |
| Example 13 | P5 (compounds 1, 4, 5) | 0.705 |
| Example 14 | P6 (compounds 1, 2, 5) | 0.690 |
| Example 15 | P7 (compounds 4, 2, 5) | 0.700 |
| Example 16 | P8 (compounds 1, 4, 2, 5) | 0.690 |
| Comparative | PIV (compounds 4, 5) | 0.525 |
| Example 4 | | |
| Comparative | PV (compounds 1, 5) | 0.600 |
| Example 5 | | |

### Example 17

### (Production of Composition Comprising Solvent And Organic Photoelectric Conversion Element)

An organic photoelectric conversion element is produced in the same manner as that in Example 9 except that C70-PCBM (phenyl 71-butyric acid methyl ester: manufactured by American Dye Source Inc., product name: ADS71BFA, hereinafter using the same product as C70-PCBM) is used instead of C60-PCBM which is an the n-type semiconductor material.

### Example 18

### (Production of Composition Comprising Solvent And Organic Photoelectric Conversion Element)

An organic photoelectric conversion element is produced in the same manner as that in Example 9 except that a mixture of C60-PCBM and C70-PCBM (C60-PCBM:C70-PCBM=80:20, manufactured by Frontier Carbon Corporation, E124, Lot. 13A0093-A, hereinafter using the same lot as the mixture of C60-PCBM and C70-PCBM) is used instead of C60-PCBM which is an the n-type semiconductor material.

### Example 19

### (Production of Composition Comprising Solvent And Organic Photoelectric Conversion Element)

An organic photoelectric conversion element is produced in the same manner as that in Example 9 except that tetrahydronaphthalene (tetralin) is used instead of ortho-dichlorobenzene as the solvent for dissolving the polymer compound P1 and C60-PCBM, and the compounds are dissolved at 120° C. for 15 hours while being heated and stirred.

### Example 20

### (Production of Composition Comprising Solvent And Organic Photoelectric Conversion Element)

An organic photoelectric conversion element is produced in the same manner as that in Example 19 except that C70-PCBM is used instead of C60-PCBM which is an n-type semiconductor material.

### Example 21

### (Production of Composition Comprising Solvent And Organic Photoelectric Conversion Element)

An organic photoelectric conversion element is produced in the same manner as that in Example 19 except that the mixture of C60-PCBM and C70-PCBM is used instead of C60-PCBM which is an n-type semiconductor material in Example 19.

### Example 22

### (Production of Composition Comprising Solvent And Organic Photoelectric Conversion Element)

An organic photoelectric conversion element was produced in the same manner as that in Example 9 except that AQ1300 manufactured by Solvay was used instead of AI4083 which is a hole transport material, applied onto the ITO film by spin coating, and heated and dried in the atmosphere at 200° C. for 10 minutes to produce a film.

### Example 23

### (Production of Composition Comprising Solvent And Organic Photoelectric Conversion Element)

An organic photoelectric conversion element is produced in the same manner as that in Example 22 except that C70-PCBM is used instead of C60-PCBM which is an n-type semiconductor material.

### Example 24

### (Production of Composition Comprising Solvent And Organic Photoelectric Conversion Element)

An organic photoelectric conversion element is produced in the same manner as that in Example 22 except that the mixture of C60-PCBM and C70-PCBM is used instead of C60-PCBM which is an n-type semiconductor material.

### Example 25

### (Production of Composition Comprising Solvent And Organic Photoelectric Conversion Element)

An organic photoelectric conversion element was produced in the same manner as that in Example 22 except that tetrahydronaphthalene (tetralin) was used instead of ortho-dichlorobenzene as the solvent for dissolving the polymer compound P1 and C60-PCBM, and the compounds were dissolved at 120° C. for 15 hours while being heated and stirred.

### Example 26

### (Production of Composition Comprising Solvent And Organic Photoelectric Conversion Element)

An organic photoelectric conversion element was produced in the same manner as that in Example 25 except that C70-PCBM was used instead of C60-PCBM which is an n-type semiconductor material.

### Example 27

### (Production of Composition Comprising Solvent And Organic Photoelectric Conversion Element)

An organic photoelectric conversion element was produced in the same manner as that in Example 25 except that the mixture of C60-PCBM and C70-PCBM was used instead of C60-PCBM which is an n-type semiconductor material.

### Example 28

### (Production of Composition Comprising Solvent And Organic Photoelectric Conversion Element)

A glass substrate having an ITO film with a 150 nm thickness deposited by a sputtering method was subjected to an ozone-UV treatment to perform a surface treatment. Next, an isopropanol dispersion of zinc oxide (ZnO) (manufactured by TAYCA Co., Ltd., a product comprising 20 wt % ZnO) was applied as an electron transport layer onto the ITO film by spin coating, and was heated at 140° C. for 10 minutes in the atmosphere to produce a film having a thickness of about 40 nm.

Next, the polymer compound P1 as a p-type semiconductor material and C60-PCBM as an n-type semiconductor material were weighed so that the ratio of the weight of C60-PCBM to the weight of the polymer compound P1 was 2, and the mixture was heated and stirred at 50° C. for 15 hours using ortho-dichlorobenzene as an ink solvent to produce an ink. The sum of the weight of the polymer compound P1 and the weight of the C60-PCBM, relative to the weight of the ink, was 1.5% by weight. The ink was applied onto ZnO by spin coating to produce an organic film comprising the polymer compound P1. The film thickness was about 100 nm. Thereafter, AI4083 as a hole transport material was applied onto the active layer by spin coating, and was heated at 70° C. for 2 minutes in the atmosphere to produce a film having a thickness of about 40 nm. Then, silver was vapor-deposited to have a thickness of 450 nm to produce an organic photovoltaic element.

### Example 29

### (Production of Composition Comprising Solvent And Organic Photoelectric Conversion Element)

An organic photoelectric conversion element is produced in the same manner as that in Example 28 except that C70-PCBM is used instead of C60-PCBM which is an n-type semiconductor material.

### Example 30

### (Production of Composition Comprising Solvent And Organic Photoelectric Conversion Element)

An organic photoelectric conversion element is produced in the same manner as that in Example 28 except that the mixture of C60-PCBM and C70-PCBM is used instead of C60-PCBM which is an n-type semiconductor material.

### Example 31

### (Production of Composition Comprising Solvent And Organic Photoelectric Conversion Element)

An organic photoelectric conversion element is produced in the same manner as that in Example 28 except that tetrahydronaphthalene (tetralin) is used instead of ortho-dichlorobenzene as the solvent for dissolving the polymer compound P1 and C60-PCBM, and the compounds are dissolved at 120° C. for 15 hours while being heated and stirred.

### Example 32

### (Production of Composition Comprising Solvent And Organic Photoelectric Conversion Element)

An organic photoelectric conversion element is produced in the same manner as that in Example 31 except that C70-PCBM is used instead of C60-PCBM which is an n-type semiconductor material.

### Example 33

### (Production of Composition Comprising Solvent And Organic Photoelectric Conversion Element)

An organic photoelectric conversion element is produced in the same manner as that in Example 31 except that the mixture of C60-PCBM and C70-PCBM is used instead of C60-PCBM which is an n-type semiconductor material.

### Example 34

### (Production of Composition Comprising Solvent And Organic Photoelectric Conversion Element)

An organic photoelectric conversion element was produced in the same manner as that in Example 28 except that AQ1300 manufactured by Solvay is used instead of AI4083 which is a hole transport material, applied onto the active layer by spin coating, and heated and dried in the atmosphere at 200° C. for 10 minutes to produce a film.

### Example 35

### (Production of Composition Comprising Solvent And Organic

Photoelectric Conversion Element)

An organic photoelectric conversion element is produced in the same manner as that in Example 34 except that C70-PCBM is used instead of C60-PCBM which is an n-type semiconductor material.

### Example 36

### (Production of Composition Comprising Solvent And Organic Photoelectric Conversion Element)

An organic photoelectric conversion element is produced in the same manner as that in Example 34 except that the mixture of C60-PCBM and C70-PCBM is used instead of C60-PCBM which is an n-type semiconductor material.

### Example 37

### (Production of Composition Comprising Solvent And Organic Photoelectric Conversion Element)

An organic photoelectric conversion element was produced in the same manner as that in Example 34 except that tetrahydronaphthalene (tetralin) was used instead of ortho-dichlorobenzene as the solvent for dissolving the polymer compound P1 and C60-PCBM, and the compounds were dissolved at 120° C. for 15 hours while being heated and stirred.

### Example 38

### (Production of Composition Comprising Solvent And Organic Photoelectric Conversion Element)

An organic photoelectric conversion element is produced in the same manner as that in Example 37 except that C70-PCBM is used instead of C60-PCBM which is an n-type semiconductor material.

### Example 39

### (Production of Composition Comprising Solvent And Organic Photoelectric Conversion Element)

An organic photoelectric conversion element is produced in the same manner as that in Example 37 except that the mixture of C60-PCBM and C70-PCBM is used instead of C60-PCBM which is an n-type semiconductor material.

### Example 40

### (Production of Composition Comprising Solvent And Organic Photoelectric Conversion Element)

An organic photoelectric conversion element is produced in the same manner as that in Example 28 except that a solution obtained by diluting polyethyleneimine ethoxylate (PEIE) (manufactured by Aldrich, product name: polyethyleneimine/80% ethoxylated solution, weight-average molecular weight approx. 70,000) instead of zinc oxide as an electron transport material with deionized water by 50 times is applied onto the ITO electrode by spin coating (number of revolutions 4000 rpm, 30 seconds).

### Example 41

### (Production of Composition Comprising Solvent And Organic Photoelectric Conversion Element)

An organic photoelectric conversion element is produced in the same manner as that in Example 40 except that C70-PCBM is used instead of C60-PCBM which is an n-type semiconductor material.

### Example 42

### (Production of Composition Comprising Solvent And Organic Photoelectric Conversion Element)

An organic photoelectric conversion element is produced in the same manner as that in Example 40 except that the mixture of C60-PCBM and C70-PCBM is used instead of C60-PCBM which is an n-type semiconductor material.

### Example 43

### (Production of Composition Comprising Solvent And Organic Photoelectric Conversion Element)

An organic photoelectric conversion element is produced in the same manner as that in Example 40 except that tetrahydronaphthalene (tetralin) is used instead of ortho-dichlorobenzene as the solvent for dissolving the polymer compound P1 and C60-PCBM, and the compounds are dissolved at 120° C. for 15 hours while being heated and stirred.

### Example 44

### (Production of Composition Comprising Solvent And Organic Photoelectric Conversion Element)

An organic photoelectric conversion element is produced in the same manner as that in Example 43 except that C70-PCBM is used instead of C60-PCBM which is an n-type semiconductor material.

### Example 45

### (Production of Composition Comprising Solvent And Organic Photoelectric Conversion Element)

An organic photoelectric conversion element is produced in the same manner as that in Example 43 except that the mixture of C60-PCBM and C70-PCBM is used instead of C60-PCBM which is an n-type semiconductor material.

### Example 46

### (Production of Composition Comprising Solvent And Organic Photoelectric Conversion Element)

An organic photoelectric conversion element was produced in the same manner as that in Example 40 except that AQ1300 manufactured by Solvay was used instead of AI4083 which is a hole transport material, applied onto the active layer by spin coating, and heated and dried in the atmosphere at 200° C. for 10 minutes to produce a film.

### Example 47

### (Production of Composition Comprising Solvent And Organic Photoelectric Conversion Element)

An organic photoelectric conversion element is produced in the same manner as that in Example 47 except that C70-PCBM is used instead of C60-PCBM which is an n-type semiconductor material.

### Example 48

### (Production of Composition Comprising Solvent And Organic Photoelectric Conversion Element)

An organic photoelectric conversion element is produced in the same manner as that in Example 46 except that the mixture of C60-PCBM and C70-PCBM is used instead of C60-PCBM which is an n-type semiconductor material.

### Example 49

### (Production of Composition Comprising Solvent And Organic Photoelectric Conversion Element)

An organic photoelectric conversion element is produced in the same manner as that in Example 49 except that tetrahydronaphthalene (tetralin) is used instead of ortho-dichlorobenzene as the solvent for dissolving the polymer compound P1 and C60-PCBM, and the compounds are dissolved at 120° C. for 15 hours while being heated and stirred.

### Example 50

### (Production of Composition Comprising Solvent And Organic Photoelectric Conversion Element)

An organic photoelectric conversion element is produced in the same manner as that in Example 49 except that C70-PCBM is used instead of C60-PCBM which is an n-type semiconductor material.

### Example 51

### (Production of Composition Comprising Solvent And Organic Photoelectric Conversion Element)

An organic photoelectric conversion element is produced in the same manner as that in Example 49 except that the mixture of C60-PCBM and C70-PCBM is used instead of C60-PCBM which is an n-type semiconductor material.

### Example 52

### (Use of Organic Photoelectric Conversion Element as Organic Thin Film Solar Cell)

When the organic photoelectric conversion element produced in Example 9 is irradiated with constant light using a fluorescent lamp in a room, the organic photoelectric conversion element can be used as an organic thin film solar cell.

### Example 53

### (Use of Organic Photoelectric Conversion Element as Organic Optical Sensor)

The organic photoelectric conversion element produced in Example 9 can be used as an organic optical sensor for detecting an output due to a signal current generated by irradiating it with light from a light source (solar light, LED, fluorescent lamp) in a state where a voltage is applied between the electrodes.

### INDUSTRIAL APPLICABILITY

According to the present invention, a polymer compound capable of producing an organic photoelectric conversion element having a large value of fill factor and the organic photoelectric conversion element can be provided.

1. A polymer compound having a structural unit represented by the formula (I) and a structural unit represented by the formula (II): [chemical structure]
in the formula (I),
X¹ and X² each independently represent a sulfur atom or an oxygen atom,
Y¹ and Y² each independently represent C—(R⁵) or a nitrogen atom,
R¹, R², and R⁵ each independently represent a hydrogen atom, an alkyl group of 1 to 30 carbon atoms optionally having a substituent, a cycloalkyl group of 3 to 30 carbon atoms optionally having a substituent, an alkenyl group of 2 to 30 carbon atoms optionally having a substituent, a cycloalkenyl group of 3 to 30 carbon atoms optionally having a substituent, an alkynyl group of 2 to 30 carbon atoms optionally having a substituent, a cycloalkynyl group of 4 to 30 carbon atoms optionally having a substituent, an alkoxy group of 1 to 30 carbon atoms optionally having a substituent, a cycloalkoxy group of 3 to 30 carbon atoms optionally having a substituent, an alkylthio group of 1 to 30 carbon atoms optionally having a substituent, a cycloalkylthio group of 3 to 30 carbon atoms optionally having a substituent, a group represented by —C(═O)—R of 2 to 30 carbon atoms (R represents a hydrogen atom, an alkyl group, an aryl group, an alkoxy group, an aryloxy group, or a monovalent heterocyclic group), an aryl group of 6 to 30 carbon atoms optionally having a substituent, an aryloxy group of 6 to 30 carbon atoms optionally having a substituent, an arylthio group of 6 to 30 carbon atoms optionally having a substituent, a monovalent heterocyclic group of 2 to 30 carbon atoms optionally having a substituent, or a halogen atom; [chemical structure]
in the formula (II),
X³ and X⁴ each independently represent a sulfur atom or an oxygen atom,
Y³ and Y⁴ each independently represent C—(R⁶) or a nitrogen atom,
R³, R⁴, and R⁶ each independently represent a hydrogen atom, an alkyl group of 1 to 30 carbon atoms optionally having a substituent, a cycloalkyl group of 3 to 30 carbon atoms optionally having a substituent, an alkenyl group of 2 to 30 carbon atoms optionally having a substituent, a cycloalkenyl group of 3 to 30 carbon atoms optionally having a substituent, an alkynyl group of 2 to 30 carbon atoms optionally having a substituent, a cycloalkynyl group of 4 to 30 carbon atoms optionally having a substituent, an alkoxy group of 1 to 30 carbon atoms optionally having a substituent, a cycloalkoxy group of 3 to 30 carbon atoms optionally having a substituent, an alkylthio group of 1 to 30 carbon atoms optionally having a substituent, a cycloalkylthio group of 3 to 30 carbon atoms optionally having a substituent, a group represented by —C(═O)—R of 2 to 30 carbon atoms (R represents a hydrogen atom, an alkyl group, an aryl group, an alkoxy group, an aryloxy group, or a monovalent heterocyclic group), an aryl group of 6 to 30 carbon atoms optionally having a substituent, an aryloxy group of 6 to 30 carbon atoms optionally having a substituent, an arylthio group of 6 to 30 carbon atoms optionally having a substituent, a monovalent heterocyclic group of 2 to 30 carbon atoms optionally having a substituent, or a halogen atom;
provided that there is no case where R¹ and R³ are the same and R² and R⁴ are the same at the same time.

2. The polymer compound according to claim 1, wherein X¹, X², X³, and X⁴ are all a sulfur atom, and Y¹, Y², Y³, and Y⁴ are all C—H.

3. The polymer compound according to claim 1, wherein R¹, R², R³, and R⁴ are an alkyl group of 1 to 30 carbon atoms optionally having a substituent, and R¹ and R² are the same and R³ and R⁴ are the same.

4. The polymer compound according to claim 1, wherein R¹, R², R³, and R⁴ are each independently an alkyl group of 12 to 19 carbon atoms optionally having a substituent.

5. The polymer compound according to claim 1, further having a structural unit represented by the formula (III):
—Ar— (III)
in the formula (III),
a group represented by —Ar— represents an arylene group of 6 to 60 carbon atoms optionally having a substituent, or a divalent heterocyclic group optionally having a substituent,
provided that the structural unit represented by the formula (III) is different from the structural units represented by the formula (I) and the formula (II).

6. The polymer compound according to claim 5, wherein the structural unit represented by the formula (III) is a structural unit represented by any of the formula (III-1) to formula (III-18), [chemical structure] [chemical structure] [chemical structure]
in each of the formulae,
R^{a}, R^{b}, R^{c}, and R^{d} each independently represent a hydrogen atom, an alkyl group of 1 to 30 carbon atoms optionally having a substituent, a cycloalkyl group of 3 to 30 carbon atoms optionally having a substituent, an alkenyl group of 2 to 30 carbon atoms optionally having a substituent, a cycloalkenyl group of 3 to 30 carbon atoms optionally having a substituent, an alkynyl group of 2 to 30 carbon atoms optionally having a substituent, a cycloalkynyl group of 4 to 30 carbon atoms optionally having a substituent, an alkoxy group of 1 to 30 carbon atoms optionally having a substituent, a cycloalkoxy group of 3 to 30 carbon atoms optionally having a substituent, an alkylthio group of 1 to 30 carbon atoms optionally having a substituent, a cycloalkylthio group of 3 to 30 carbon atoms optionally having a substituent, a group represented by —C(═O)—R of 2 to 30 carbon atoms (R represents a hydrogen atom, an alkyl group, an aryl group, an alkoxy group, an aryloxy group, or a monovalent heterocyclic group), an aryl group of 6 to 30 carbon atoms optionally having a substituent, an aryloxy group of 6 to 30 carbon atoms optionally having a substituent, an arylthio group of 6 to 30 carbon atoms optionally having a substituent, a monovalent heterocyclic group of 2 to 30 carbon atoms optionally having a substituent, or a halogen atom, and
X^{a} and X^{b} each independently represent a sulfur atom or an oxygen atom.

7. The polymer compound according to claim 6, wherein the structural unit represented by the formula (III) is a structural unit represented by the formula (III-1) or the formula (III-15).

8. The polymer compound according to claim 1, further comprising a structural unit represented by the formula (IV): [chemical structure]
in the formula (IV),
X⁵ and X⁶ each independently represent a sulfur atom or an oxygen atom,
Y⁵ and Y⁶ each independently represent C—(R⁹) or a nitrogen atom,
R⁷, R⁸, and R⁹ each independently represent a hydrogen atom, an alkyl group of 1 to 30 carbon atoms optionally having a substituent, a cycloalkyl group of 3 to 30 carbon atoms optionally having a substituent, an alkenyl group of 2 to 30 carbon atoms optionally having a substituent, a cycloalkenyl group of 3 to 30 carbon atoms optionally having a substituent, an alkynyl group of 2 to 30 carbon atoms optionally having a substituent, a cycloalkynyl group of 4 to 30 carbon atoms optionally having a substituent, an alkoxy group of 1 to 30 carbon atoms optionally having a substituent, a cycloalkoxy group of 3 to 30 carbon atoms optionally having a substituent, an alkylthio group of 1 to 30 carbon atoms optionally having a substituent, a cycloalkylthio group of 3 to 30 carbon atoms optionally having a substituent, a group represented by —C(═O)—R of 2 to 30 carbon atoms (R represents a hydrogen atom, an alkyl group, an aryl group, an alkoxy group, an aryloxy group, or a monovalent heterocyclic group), an aryl group of 6 to 30 carbon atoms optionally having a substituent, an aryloxy group of 6 to 30 carbon atoms optionally having a substituent, an arylthio group of 6 to 30 carbon atoms optionally having a substituent, a monovalent heterocyclic group of 2 to 30 carbon atoms optionally having a substituent, or a halogen atom;
provided that the structural unit represented by the formula (IV) represents a structural unit different from either the structural unit represented by the formula (I) or the structural unit represented by the formula (II) which the polymer compound has.

9. A composition comprising the polymer compound according to claim 1, and an electron-acceptor compound.

10. The composition according to claim 9, wherein the electron-acceptor compound is a fullerene derivative.

11. The composition according to claim 9, further comprising a solvent.

12. An organic photoelectric conversion element comprising a first electrode, a second electrode, and an active layer disposed between the first electrode and the second electrode, wherein the active layer comprises the polymer compound according to claim 1.

13. An organic thin film solar cell comprising the organic photoelectric conversion element according to claim 12.

14. An organic optical sensor comprising the organic photoelectric conversion element according to claim 12.
